(19) United States
(12) Patent Application Publication
(10) Pub. No.: US 2025/0378855 A1
(43) Pub. Date: Dec. 11, 2025

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventors: Tatsuki KOSHIDA, Yokkaichi Mie (JP); Takayuki ISHIKAWA, Yokkaichi Mie (JP); Tetsu MOROOKA, Yokkaichi Mie (JP); Yefei HAN, Yokohama Kanagawa (JP); Fumie KIKUSHIMA, Yokkaichi Mie (JP); Kazuhiro YAMAUCHI, Yokkaichi Mie (JP)

(73) Assignee: Kioxia Corporation, Tokyo (JP)

(21) Appl. No.: 19/070,328

(22) Filed: Mar. 4, 2025

(30) Foreign Application Priority Data
Jun. 6, 2024 (JP) 2024-091993

(51) Int. Cl. G11C 5/06; H10B 43/10; H10B 43/27

(52) U.S. Cl. CPC G11C 5/063; H10B 43/10; H10B 43/27

(57) ABSTRACT

A pillar of a semiconductor memory device of an embodiment includes a semiconductor layer extending in a stacking direction in a stacked body, first and second insulating layers sequentially covering a side wall of the semiconductor layer from a semiconductor layer side, and a plurality of fragment layers each of that a third insulating layer scattered at height positions of the plurality of conductive layers interposed between the first and second insulating layers, and the first insulating layer includes a first portion in which an outer shape at a first height position located between both end portions in a thickness direction of each of the plurality of conductive layers is a first distance in a first direction along the plurality of conductive layers, and a second portion in which an outer shape at a second height position located between height positions of the both end portions of the plurality of conductive layers and the first height position is a second distance larger than the first distance in the first direction.

### CROSS-REFERENCE TO RELATED APPLICATIONS

This application is based upon and claims the benefit of priority from Japanese Patent Application No. 2024-091993, filed on Jun. 6, 2024; the entire contents of which are incorporated herein by reference.

### FIELD

Embodiments described herein relate generally to a semiconductor memory device and a method for manufacturing the semiconductor memory device.

### BACKGROUND

In order to increase the storage capacity of a semiconductor memory device such as a three-dimensional nonvolatile memory, attempts have been made to reduce the layer thickness of a plurality of conductive layers to increase the number of stacked layers. In order to suppress interference between memory cells formed at the height positions of the plurality of conductive layers as the layer thickness of the plurality of conductive layers is reduced, it is effective to divide a charge storage layer holding data by storing charges for each memory cell.

### BRIEF DESCRIPTION OF THE DRAWINGS

FIGS. 1A and 1B are views illustrating a schematic configuration example of a semiconductor memory device according to a first embodiment;

FIGS. 2A and 2B are cross-sectional views along a Y direction illustrating an example of a configuration of the semiconductor memory device according to the first embodiment;

FIGS. 3A to 3D are schematic views describing stacked bodies included in the semiconductor memory device according to the first embodiment;

FIGS. 4A to 4D are views sequentially illustrating a part of a procedure of a method for manufacturing the semiconductor memory device according to the first embodiment;

FIGS. 5A to 5C are views sequentially illustrating a part of the procedure of the method for manufacturing the semiconductor memory device according to the first embodiment;

FIGS. 6A to 6D are views sequentially illustrating a part of the procedure of the method for manufacturing the semiconductor memory device according to the first embodiment;

FIGS. 7A to 7C are views sequentially illustrating a part of the procedure of the method for manufacturing the semiconductor memory device according to the first embodiment;

FIGS. 8A to 8H are enlarged cross-sectional views sequentially illustrating a part of a procedure of a method for forming a memory layer according to the first embodiment;

FIGS. 9A to 9G are enlarged cross-sectional views sequentially illustrating a part of the procedure of the method for forming the memory layer according to the first embodiment;

FIG. 10 is an enlarged cross-sectional view at a height position of a word line and select gate lines of a pillar included in a semiconductor memory device according to a first modification of the first embodiment;

FIG. 11 is an enlarged cross-sectional view at a height position of a word line and select gate lines of a pillar included in a semiconductor memory device according to a second modification of the first embodiment;

FIG. 12 is an enlarged cross-sectional view at a height position of a word line and select gate lines of a pillar included in a semiconductor memory device according to a third modification of the first embodiment;

FIGS. 13A to 13H are enlarged cross-sectional views illustrating configuration examples of pillars included in a semiconductor memory device according to other modifications of the first embodiment;

FIG. 14 is an enlarged cross-sectional view at a height position of a word line and select gate lines of a pillar included in a semiconductor memory device according to a second embodiment;

FIGS. 15A to 15G are enlarged cross-sectional views sequentially illustrating a part of a procedure of a method for forming a memory layer according to the second embodiment; and

FIGS. 16A to 16H are enlarged cross-sectional views illustrating configuration examples of pillars included in a semiconductor memory device according to other modifications of the second embodiment.

### DETAILED DESCRIPTION

A semiconductor memory device of an embodiment includes: a stacked body in which a plurality of conductive layers is stacked apart from each other; and a pillar that extends in the stacked body in a stacking direction of the stacked body, wherein the pillar includes a semiconductor layer extending in the stacking direction in the stacked body, first and second insulating layers sequentially covering a side wall of the semiconductor layer from a semiconductor layer side, and a plurality of fragment layers each of that is a third insulating layer scattered at height positions of the plurality of conductive layers interposed between the first and second insulating layers, the third insulating layer containing a material different from a material of the first and second insulating layer, and the first insulating layer includes a first portion in which an outer shape at a first height position located between both end portions in a thickness direction of each of the plurality of conductive layers is a first distance in a first direction along the plurality of conductive layers, the first position being located at a height position facing each of the plurality of fragment layers, and a second portion in which an outer shape at a second height position located between height positions of the both end portions of the plurality of conductive layers and the first height position is a second distance larger than the first distance in the first direction, the second position being located at the height position facing each of the plurality of fragment layers.

Hereinafter, embodiments of the present invention will be described in detail with reference to the drawings. Note that the present invention is not limited by the embodiments described below. In addition, constituent elements in the embodiments described below include those that can be easily assumed by those skilled in the art or those that are substantially the same.

### First Embodiment

Hereinafter, a first embodiment will be described in detail with reference to the drawings.

### (Configuration Example of Semiconductor Memory Device)

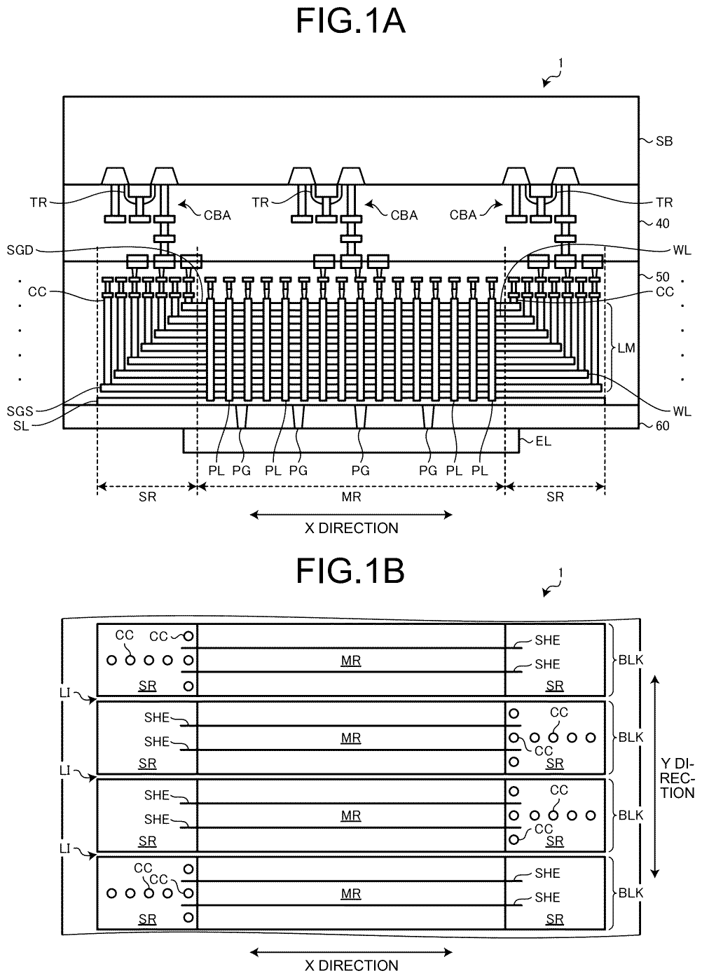

FIGS. 1A and 1B are views illustrating a schematic configuration example of a semiconductor memory device 1 according to the first embodiment. More specifically, FIG. 1A is a cross-sectional view of the semiconductor memory device 1 along an X direction, and FIG. 1B is a schematic plan view illustrating a layout of the semiconductor memory device 1.

However, in FIG. 1A, hatching is omitted in consideration of visibility of the drawing. In addition, in FIG. 1A, configurations that do not necessarily exist in the same cross section are illustrated, and a part of upper layer wiring and the like is omitted.

In addition, in the present specification, both the X direction and the Y direction are directions along the orientation of surfaces of word lines WL, and the X direction and the Y direction are orthogonal to each other. In addition, the electrical lead-out direction of the word lines WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes an electrode film EL, a source line SL, one or more select gate lines SGS, a plurality of word lines WL, one or more select gate lines SGD, and a semiconductor substrate SB on which peripheral circuits CBA are provided in order from the lower side of the drawing.

The source line SL is disposed on the electrode film EL via an insulating layer 60. A plurality of plugs PG is disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL. The select gate lines SGS, the plurality of word lines WL, and the select gate lines SGD are stacked in this order on the source line SL.

As illustrated in FIGS. 1A and 1B, a memory region MR is disposed at a central portion of the plurality of word lines WL and the like in the X direction, and staircase regions SR are disposed at both end portions of the plurality of word lines WL and the like in the X direction. The memory region MR and the staircase regions SR are divided into a plurality of regions by a plurality of plate-like contacts LI penetrating the plurality of word lines WL and the like and extending in the direction along the X direction.

Note that regions disposed between the plate-like contacts LI adjacent in the Y direction and including the memory region MR and the staircase regions SR are referred to as block regions BLK. As will be described below, the memory region MR includes a plurality of memory cells that holds data in a nonvolatile manner, and the above-described block region BLK is an erase unit of the data.

In addition, between the plate-like contacts LI adjacent in the Y direction, a plurality of separation layers SHE penetrating the select gate lines SGD and extending in the direction along the X direction is disposed. The plurality of separation layers SHE extends in the direction along the X direction over the entire memory region MR and reaches a part of the staircase regions SR at both end portions in the X direction.

In the memory region MR, a plurality of pillars PL penetrating the word lines WL and the select gate lines SGD and SGS in the stacking direction thereof is disposed. The lower ends of the pillars PL reach the source line SL. A plurality of memory cells is formed at intersection portions of the pillars PL and the word lines WL. As a result, the semiconductor memory device 1 is configured as, for example, a three-dimensional nonvolatile memory in which memory cells are three-dimensionally disposed in the memory region MR.

In the staircase regions SR, the plurality of word lines WL and the select gate lines SGD and SGS are processed in a staircase shape and terminate. At this time, as the distance from the memory region MR increases in the X direction, the plurality of word lines WL and the select gate lines SGD and SGS constituting terrace portions shift from the upper layer side to the lower layer side, so that the height position of the terrace portion lowers toward the source line SL side.

Note that, in the present specification, the direction in which the terrace surfaces of the plurality of word lines WL and the select gate lines SGD and SGS face is defined as the upper side of the semiconductor memory device 1.

The separation layers SHE described above extend from the memory region MR to a portion of the staircase regions SR where the select gate lines SGD are processed into a staircase shape. As a result, in one block region BLK, the select gate lines SGD are separated into a plurality of regions. In other words, the separation layers SHE penetrate the portions above the plurality of word lines WL, so that these upper layer portions are partitioned into patterns of the plurality of select gate lines SGD.

Contacts CC connected to the word lines WL and the select gate lines SGD and SGS of layers are disposed at terrace portions of steps including the plurality of word lines WL and the select gate lines SGD and SGS. In the word lines WL and the select gate lines SGS, one contact CC is connected for each layer. In the select gate lines SGD, one contact CC is connected for each section separated by the separation layers SHE per layer.

Here, in one block region BLK, the plurality of contacts CC is disposed on one of the staircase regions SR on both sides in the X direction. In addition, when viewed on one side in the X direction, for example, the plurality of contacts CC is disposed every two block regions BLK.

That is, in the example of FIG. 1B, in the uppermost block region BLK in the drawing, a plurality of contacts CC is disposed, for example, in the staircase region SR on the left side in the drawing out of the staircase regions SR at both end portions in the X direction. In addition, in the block regions BLK one below and two below the above-described block region BLK, a plurality of contacts CC is disposed in the staircase region SR on the right side in the drawing out of the staircase regions SR at both end portions in the X direction. Further, in the lowermost block region BLK in the drawing, a plurality of contacts CC is disposed in the staircase region SR again on the left side in the drawing.

Accordingly, the contacts CC of the staircase regions SR at both end portions in the X direction illustrated in FIG. 1A belong to different block regions BLK, and are not actually located in the same cross section.

The word lines WL and the like stacked in multiple layers are individually led out by these contacts CC. More specifically, a write voltage, a read voltage, and the like are applied from these contacts CC to the memory cells included in the memory region MR at the central portion of the plurality of word lines WL via the word lines WL at the same height positions as the memory cells.

The plurality of word lines WL, the select gate lines SGD and SGS, the pillars PL, and the contacts CC are covered with an insulating layer 50. The insulating layer 50 also extends around these configurations including the plurality of word lines WL and the like.

The semiconductor substrate SB above the insulating layer 50 covering the above configurations is, for example, a silicon substrate or the like. The peripheral circuits CBA including transistors TR, wiring, and the like are disposed on the surface of the semiconductor substrate SB. Various voltages applied from the contacts CC to the memory cells are controlled by the peripheral circuits CBA electrically connected to the contacts CC. As a result, the peripheral circuits CBA control the electrical operation of the memory cells.

The peripheral circuits CBA are covered with an insulating layer 40, and the insulating layer 40 and the insulating layer 50 covering the plurality of word lines WL and the like are joined to form the semiconductor memory device 1 including the configurations of the plurality of word lines WL and the select gate lines SGD and SGS, the pillars PL, the contacts CC, and the like, and the peripheral circuits CBA.

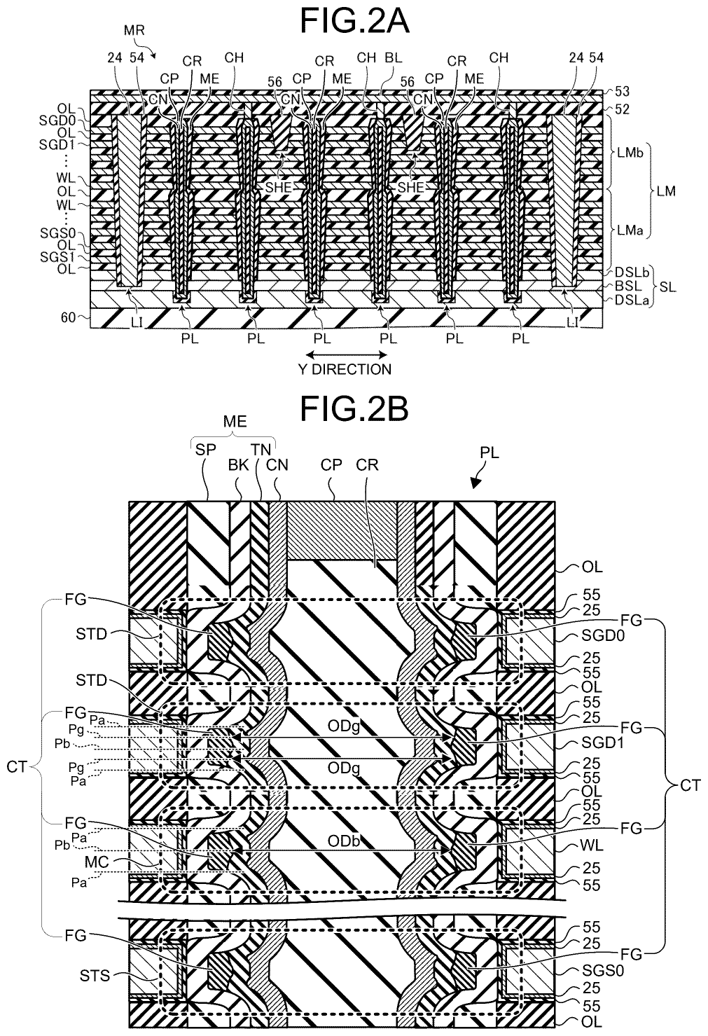

Next, a detailed configuration example of the semiconductor memory device 1 will be described with reference to FIGS. 2A and 2B. FIGS. 2A and 2B are cross-sectional views along the Y direction illustrating an example of a configuration of the semiconductor memory device 1 according to the first embodiment.

More specifically, FIG. 2A is a cross-sectional view of the memory region MR of the semiconductor memory device 1. In FIG. 2A, structures below the insulating layer 60 and above an insulating layer 53 described below are omitted. FIG. 2B is an enlarged cross-sectional view of the pillar PL at the height positions of the word line WL and the select gate lines SGD and SGS.

As illustrated in FIG. 2A, the source line SL has a multilayer structure in which, for example, a lower source line DSLa, an intermediate source line BSL, and an upper source line DSLb are stacked in this order on the insulating layer 60. The lower source line DSLa, the intermediate source line BSL, and the upper source line DSLb are, for example, polysilicon layers. Among them, at least the intermediate source line BSL may be a conductive polysilicon layer or the like in which impurities are diffused.

Note that the source line SL is connected to the peripheral circuits CBA via the electrode film EL by penetrating contacts, which are not illustrated, extending from the electrode film EL to the peripheral circuits CBA in the insulating layer 50 described above outside a stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. A plurality of select gate lines SGS0 and SGS1 is disposed in this order from the upper layer side of the stacked body LMa via the insulating layers OL further below the lowermost word line WL of the stacked body LMa. The stacked body LMb is disposed on the stacked body LMa. A plurality of select gate lines SGD0 and SGD1 is disposed in this order from the upper layer side of the stacked body LMb via the insulating layers OL further above the uppermost word line WL of the stacked body LMb.

However, the number of word lines WL and select gate lines SGD and SGS stacked in the stacked body LM is arbitrary. The word lines WL and the select gate lines SGD and SGS are, for example, tungsten layers or molybdenum layers. The insulating layers OL are, for example, silicon oxide layers or the like.

As illustrated in FIG. 2B, the surfaces of each of the plurality of word lines WL and the select gate lines SGD and SGS on both sides in the stacking direction of the stacked body IM are covered with a barrier metal layer 25 and a metal-containing layer 55 in this order. The surfaces of the word lines WL and the select gate lines SGD and SGS facing the side surface of the pillar PL are also covered with the barrier metal layer 25 and the metal-containing layer 55 in this order.

The barrier metal layer 25 includes, for example, at least one layer of a titanium layer, a titanium nitride layer, a tantalum layer, a tantalum nitride layer, and a molybdenum nitride layer. As a result, the barrier metal layer 25 suppresses diffusion of metal atoms such as tungsten or molybdenum constituting the word line WL or the like into another adjacent layer. The metal-containing layer 55 is a layer having a dielectric constant higher than that of a silicon oxide layer such as an aluminum oxide (Al₂O₃) layer, and functions as a block insulating layer in a memory cell MC to be described below.

As illustrated in FIG. 2A, the upper surface of the stacked body LM is covered with an insulating layer 52. The insulating layer 52 is covered with the insulating layer 53. Each of the insulating layers 52 and 53 constitutes a part of the insulating layer 50 in FIG. 1A.

As described above, the stacked body LM is divided in the Y direction by the plurality of plate-like contacts LI. That is, the plate-like contacts LI are each arranged in the Y direction and extend in the stacking direction of the stacked body LM and in a direction along the X direction.

As described above, the plate-like contacts LI continuously extend in the stacked body LM from one end portion to the other end portion of the stacked body LM in the X direction. In addition, the plate-like contacts LI penetrate the stacked body LM and the upper source line DSLb and reach the intermediate source line BSL.

In addition, the plate-like contacts LI have, for example, a tapered shape in which the width in the Y direction decreases from the upper end portion toward the lower end portion. Alternatively, the plate-like contacts LI have, for example, a bowing shape in which the width in the Y direction is maximized at a predetermined position between the upper end portion and the lower end portion.

Each of the plate-like contacts LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers the side walls of the plate-like contact LI facing each other in the Y direction. The conductive layer 24 is loaded inside the insulating layer 54, and electrically connected to the source line SL including the intermediate source line BSL. However, instead of the plate-like contact LI, a plate-like member filled with the insulating layer may penetrate the stacked body LM and extend in the direction along the X direction, thereby dividing the stacked body LM in the Y direction.

In addition, between the plate-like contacts LI adjacent in the Y direction, a plurality of separation layers SHE penetrating the upper layer portion of the stacked body LMb and extending in the direction along the X direction is disposed. These separation layers SHE are insulating layers 56 such as silicon oxide layers that penetrate the select gate lines SGD0 and SGD1 and reach the insulating layer OL immediately below the select gate line SGD1.

In other words, these separation layers SHE penetrating the upper layer portion of the stacked body LMb extend between the plate-like contacts LI in the X direction between the memory region MR and a part of the staircase regions SR, so that the upper layer portion of the stacked body LMb is partitioned into the select gate lines SGD0 and SGD1 described above.

In the memory region MR, the plurality of pillars PL penetrating the stacked body LM, the upper source line DSLb, and the intermediate source line BSL and reaching the lower source line DSLa is dispersedly disposed.

The plurality of pillars PL is disposed, for example, in a staggered manner when viewed from the stacking direction of the stacked body LM. Each pillar PL has, for example, a circular shape, an elliptical shape, an oblong shape (oval shape), or the like as a cross-sectional shape in a direction along the layering direction of the stacked body LM, that is, in a direction along the XY plane.

In addition, each of the pillars PL has a tapered shape in which the diameter and the cross-sectional area decrease from the upper layer side toward the lower layer side in a portion penetrating the stacked body LMa and a portion penetrating the stacked body LMb. Alternatively, each of the pillars PL has, for example, a bowing shape in which the diameter and the cross-sectional area are maximized at a predetermined position between the upper layer side and the lower layer side in a portion penetrating the stacked body LMa and a portion penetrating the stacked body LMb.

Each of the plurality of pillars PL includes a memory layer ME extending in the stacked body LM in the stacking direction, a channel layer CN penetrating the stacked body LM and connected to the intermediate source line BSL, a cap layer CP covering the upper surface of the channel layer CN, and a core layer CR serving as a core material of the pillar PL.

More specifically, the channel layer CN is in direct contact with the intermediate source line BSL at a depth position of the intermediate source line BSL. That is, the memory layer ME is disposed on a side surface of the pillar PL except for the depth position of the intermediate source line BSL. In addition, the memory layer ME is also disposed on the bottom surface of the pillar PL reaching the depth of the lower source line DSLa.

As illustrated in FIG. 2B, the memory layer ME has a stack structure including a spacer layer SP, a block insulating layer BK, a tunnel insulating layer TN, and a charge storage layer CT.

More specifically, the spacer layer SP covers the surfaces of the plurality of insulating layers OL facing the pillar PL. The block insulating layer BK covers the spacer layer SP at the height positions of the plurality of insulating layers OL, covers the surfaces facing the pillar PL at the height positions of the plurality of word lines WL and the select gate lines SGD and SGS, and extends in the stacking direction of the stacked body LM.

As a result, the inner shape of the block insulating layer BK has a shape retracted toward the outer peripheral side of the pillar PL with respect to the other portions at the height positions of the plurality of word lines WL and the select gate lines SGD and SGS. That is, the retraction portion of the block insulating layer BK is concave when viewed from the center direction of the pillar PL. The charge storage layer CT includes a plurality of fragment layers FG dispersedly disposed in the stacking direction of the stacked body LM so as to fit into these retraction portions of the block insulating layer BK.

Note that the height positions of the plurality of word lines WL and the select gate lines SGD and SGS are height positions from a surface on one side to a surface on the other side in the stacking direction of the stacked body LM of each of the word lines WL and the select gate lines SGD and SGS. That is, the height positions of these word lines WL and select gate lines SGD and SGS do not include the thickness of the barrier metal layer 25 in the stacking direction or the thickness of the metal-containing layer 55 in the stacking direction.

Similarly, the height positions of the plurality of insulating layers OL are height positions from a surface on one side to a surface on the other side in the stacking direction of the stacked body LM of each of the insulating layers OL.

The tunnel insulating layer TN covers the block insulating layer BK at the height positions of the plurality of insulating layers OL, covers the fragment layers FG at the height positions of the plurality of word lines WL and the select gate lines SGD and SGS, and extends in the stacking direction of the stacked body LM.

By covering the surfaces of the block insulating layer BK and the fragment layers FG included in the charge storage layer CT along the surfaces facing the tunnel insulating layer TN, the tunnel insulating layer TN also has an inner shape conforming to the inner shape of the block insulating layer BK retracted to the outer peripheral side of the pillar PL with respect to the other portions at the height positions of the plurality of word lines WL and the select gate lines SGD and SGS.

However, since the fragment layers FG of the charge storage layer CT are provided between the block insulating layer BK and the tunnel insulating layer TN, the concave and convex of the inner shape of the tunnel insulating layer TN are more alleviated than the concave and convex of the inner shape of the block insulating layer BK. Similarly, the channel layer CN extending in the stacking direction so as to cover the inner shape of the tunnel insulating layer TN also has an inner shape conforming to the inner shapes of the block insulating layer BK and the tunnel insulating layer TN.

Since the memory layer ME has the stack structure as described above, the charge storage layer CT has a divided structure in which the individual fragment layers FG are dispersedly interposed between the block insulating layer BK and the tunnel insulating layer TN at the height positions of the individual word lines WL or the select gate lines SGD and SGS.

In addition, the surface of each fragment layer FG of the charge storage layer CT facing the tunnel insulating layer TN has a shape protruding toward the inside of the pillar PL with respect to both end portions in the stacking direction at the central part in the stacking direction of the stacked body LM. As a result, an outer shape of the tunnel insulating layer TN is larger at a height position Pg facing each portion deviated from a central portion of each fragment layer FG in the stacking direction, the height position Pg being a predetermined height position positioned between a height position Pa of each of both end portions in the stacking direction of the word lines WL and the select gate lines SGD and SGS and a height position Pb facing each central part of each fragment layer FG in the stacking direction, the height position Pb being a predetermined height position positioned between both end portions in a thickness direction of each of the plurality of word lines WL and the select gate lines SGD and SGS.

In other words, for example, within the range of the height position between both end portions in the stacking direction of the fragment layers FG, the height position of the portion where the inner shape of the fragment layer FG protrudes most toward the center in the extending direction of the pillar PL can be defined as the height position Pb. In addition, within the range between the height positions of both end portions in the stacking direction of the fragment layers FG and the height position Pb, the height position of the portion where the inner shape of the fragment layer FG is most retracted from the center in the extending direction of the pillar PL can be defined as the height position Pg.

That is, when the shape of the pillar PL viewed from the stacking direction of the stacked body LM is, for example, a circle, the tunnel insulating layer TN has an outer shape in which the diameter at the height position Pb is smaller than the diameter at the height position Pg. In addition, the tunnel insulating layer TN has an outer shape in which a distance ODb in the X direction at the height position Pb is smaller than a distance ODg in the X direction at the height position Pg.

As described above, the channel layer CN penetrates the stacked body LM, the upper source line DSLb, and the intermediate source line BSL further inside the memory layer ME, reaches the depth of the lower source line DSLa, and is in contact with the intermediate source line BSL on the side surface. Thus, the channel layer CN is electrically connected to the source line SL including the intermediate source line BSL.

In addition, the cap layer CP is disposed at the upper end portion of the pillar PL so as to cover at least the upper end portion of the channel layer CN, and is connected to the channel layer CN. Further, the cap layer CP is connected to a bit line BL disposed in the insulating layer 53 via plugs CH disposed in the insulating layer 52. The bit line BL extends above the stacked body LM in the direction along the Y direction so as to intersect with the lead-out direction of the word lines WL.

Note that, in FIG. 2A, the plugs CH are connected only to three pillars PL that penetrate the select gate lines SGD separated into three and are electrically connected to the bit line BL illustrated in FIG. 2A among the six pillars PL. The other pillars PL are connected to another bit line BL extending in the direction along the Y direction in parallel with the bit line BL illustrated in FIG. 2A via plugs CH, which are not illustrated in FIG. 2A, at positions different from the cross section illustrated in FIG. 2A.

The spacer layer SP, the block insulating layer BK, and the tunnel insulating layer TN of the memory layer ME, and the core layer CR are, for example, silicon oxide layers or the like. The charge storage layer CT including the plurality of fragment layers FG is, for example, a silicon nitride layer or the like. The channel layer CN and the cap layer CP are semiconductor layers such as polysilicon layers or amorphous silicon layers.

However, the block insulating layer BK may be a metal oxide layer in addition to a silicon oxide layer or the like, or may be a layer obtained by combining a silicon oxide layer and a metal oxide layer. In addition, the tunnel insulating layer TN may be a silicon oxynitride layer or the like in addition to a silicon oxide layer or the like. In addition, in addition to the silicon nitride layer, the charge storage layer CT including the fragment layers FG may be a silicon layer, a metal oxide layer, or the like.

As illustrated in FIG. 2B, with the above configuration, a memory cell MC is formed in each portion facing the individual word lines WL on the side surface of the pillar PL. When a predetermined voltage is applied from the word line WL, data is written to and read from the memory cell MC.

In addition, a select gate STD is formed in a portion where the side surface of the pillar PL faces the select gate lines SGD0 and SGD1 above the word lines WL. In addition, a select gate STS is formed in a portion where the side surface of the pillar PL faces the select gate lines SGS0 and SGS1 below the word lines WL.

When predetermined voltages are applied from the select gate lines SGD and SGS, the select gates STD and STS are turned on or off, and the memory cells MC of the pillar PL to which the select gate STD or STS belong can be brought into a selected state or a non-selected state.

### (Method for Manufacturing Semiconductor Memory Device)

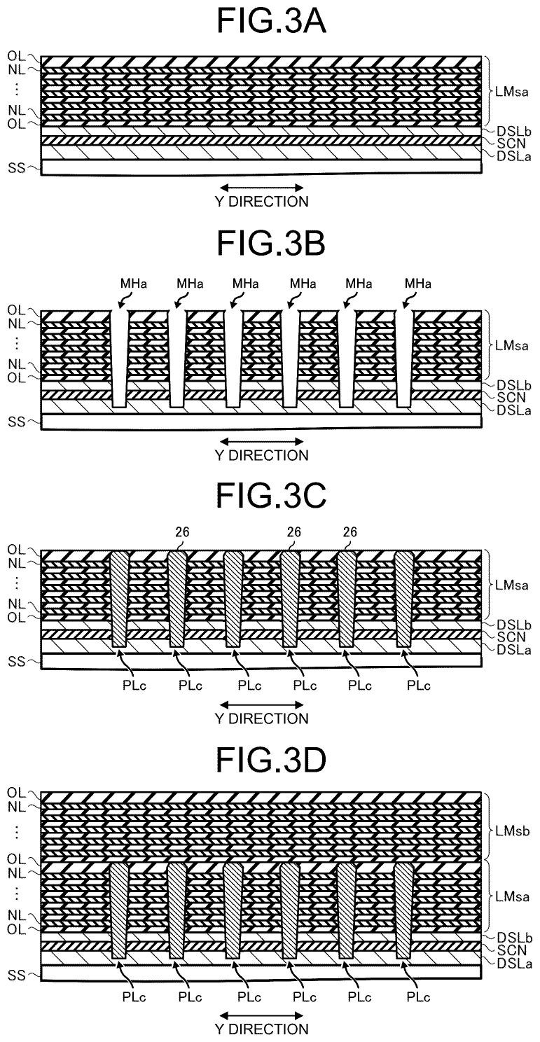

Next, a method for manufacturing the semiconductor memory device 1 of the first embodiment will be described with reference to FIGS. 3A to 9G. Among FIGS. 3A to 9G, FIGS. 3A to 7C are views sequentially illustrating a part of the procedure of the method for manufacturing the semiconductor memory device 1 according to the first embodiment. FIGS. 3A to 7C illustrate a cross-section along the Y direction of a region that becomes the memory region MR later.

As illustrated in FIG. 3A, the lower source line DSLa, an intermediate sacrificial layer SCN, and the upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 (see FIG. 2A or the like) described above may be formed on the upper surface side of the support substrate SS. The intermediate sacrificial layer SCN is, for example, a silicon nitride layer or the like, and is a layer that is replaced with a polysilicon layer or the like later and becomes the intermediate source line BSL.

A stacked body LMsa in which a plurality of insulating layers NL and the plurality of insulating layers OL are alternately stacked one by one is formed on the upper source line DSLb. The insulating layers NL are, for example, silicon nitride layers or the like, and function as sacrificial layers that are later replaced with conductive materials and become the word lines WL or the select gate lines SGS.

Thereafter, although not illustrated, the insulating layers NL and the insulating layers OL are processed into a staircase shape in a partial region of the stacked body LMsa. Such processing can be performed by repeating slimming of a mask pattern such as a photoresist layer and etching of the insulating layers NL and the insulating layers OL of the stacked body LMsa a plurality of times.

That is, a mask pattern is formed on the upper surface of the stacked body LMsa, and the insulating layer NL and the insulating layer OL in an exposed portion are etched away one by one. In addition, an end portion of the mask pattern is retracted by treatment with oxygen plasma or the like to newly expose the upper surface of the stacked body LMsa, and the insulating layer NL and the insulating layer OL are further etched away one by one. By repeating such treatment a plurality of times, the stacked body LMsa having a staircase shape is formed at both end portions in the X direction.

As illustrated in FIG. 3B, a plurality of memory holes MHa extending through the stacked body LMsa in the stacking direction is formed. The plurality of memory holes MHa penetrates the stacked body LMsa, the upper source line DSLb, and the intermediate sacrificial layer SCN and reaches the lower source line DSLa. These memory holes MHa are portions that later become lower structures of the pillars PL.

As illustrated in FIG. 3C, the memory holes MHa are filled with sacrificial layers 26 such as amorphous silicon layers or CVD-carbon layers. As a result, pillars PLc in which the plurality of memory holes MHa is filled with the sacrificial layers 26 are formed.

As illustrated in FIG. 3D, a stacked body LMsb that covers the stacked body LMsa and in which a plurality of insulating layers NL and a plurality of insulating layers OL are alternately stacked one by one is formed. The insulating layers NL of the stacked body LMsb function as sacrificial layers that are later replaced with conductive layers and become the word lines WL or the select gate lines SGD.

Thereafter, although not illustrated, the insulating layers NL and the insulating layers OL are processed into a staircase shape in a partial region of the stacked body LMsb. Such processing can be performed by repeating slimming of a mask pattern such as a photoresist layer and etching of the insulating layers NL and the insulating layers OL of the stacked body LMsb a plurality of times similarly to the treatment on the stacked body LMsa described above.

At this time, the uppermost step of the stair part formed in the stacked body LMsa and the lowermost step of the stair part formed in the stacked body LMsb are brought close to each other to form a staircase shape continuously from the lower layer side of the stacked body LMsa to the upper layer side of the stacked body LMsb. As a result, the stacked bodies LMsa and LMsb are formed in which the staircase regions SR having a staircase shape from the stacked body LMsa to the stacked body LMsb are formed at both end portions in the X direction.

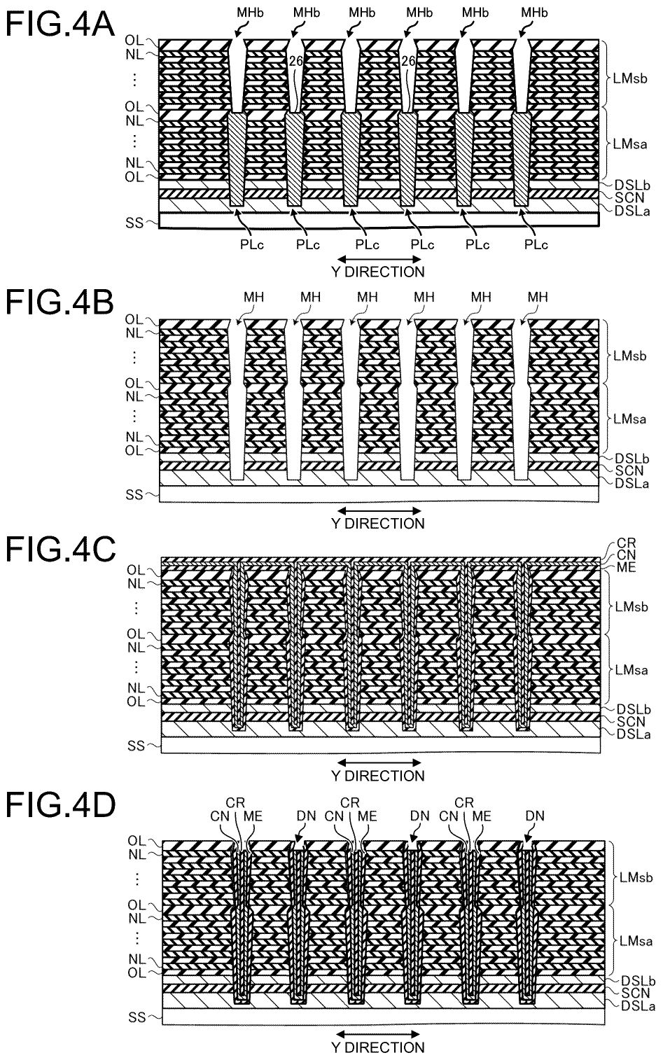

As illustrated in FIG. 4A, a plurality of memory holes MHb penetrating the stacked body LMsb and connected to the plurality of pillars PLC formed in the stacked body LMsa are formed. The memory holes MHb are portions that later become upper structures of the pillars PL.

As illustrated in FIG. 4B, the sacrificial layers 26 are removed from the pillars PLc at the bottoms of the memory holes MHb. As a result, the memory holes MHa are opened at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa is formed.

Note that, in a case where the sacrificial layers 26 loaded in the pillars PLc are CVD-carbon layers or the like, the sacrificial layers 26 can be collectively removed from these pillars PLC when the mask pattern or the like used at the time of forming the memory holes MHb in FIG. 4A described above is removed by ashing or the like using oxygen plasma.

As illustrated in FIG. 4C, the memory layer ME, the channel layer CN, and the core layer CR are formed in this order in the memory hole MH. As a result, the memory layer ME and the channel layer CN are formed on the side surface of the memory hole MH and the bottom surface where the lower source line DSLa is exposed, and the core layer CR is loaded in a central portion of the memory hole MH. The memory layer ME, the channel layer CN, and the core layer CR are also formed in this order on the upper surface of the stacked body LMsb.

Note that when the memory layer ME is formed, the charge storage layer CT over the entire stacking direction of the stacked bodies LMsa and LMsb is formed in the memory hole MH, and then the charge storage layer CT is divided such that each fragment layer FG (see FIG. 2B) is disposed at the height positions of the plurality of insulating layers NL. Details of a method for dividing the charge storage layer CT will be described below.

As illustrated in FIG. 4D, recesses DN are formed at the upper end portions of the core layers CR and the channel layers CN.

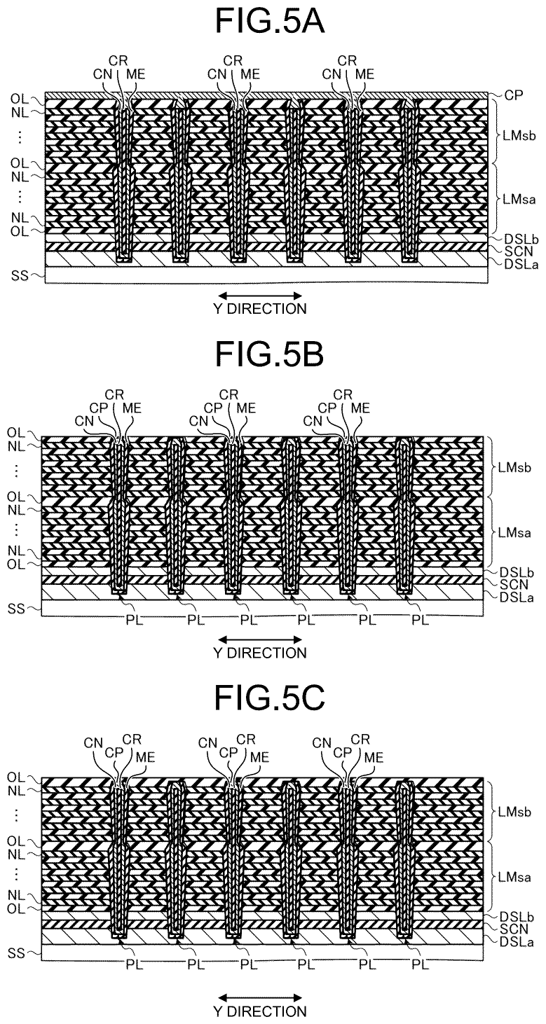

As illustrated in FIG. 5A, the cap layer CP is formed in the recesses DN at the upper end portions of the memory holes MH. The cap layer CP is also formed on the upper surface of the stacked body LMsb.

As illustrated in FIG. 5B, the memory layer ME on the upper surface of the stacked body LMsb is removed by CMP or the like, and the cap layer CP disposed at the upper end portions of the memory holes MH is formed.

As illustrated in FIG. 5C, an uppermost insulating layer OL of the stacked body LMsb thinned by CMP or the like is stacked. As a result, the pillars PL in which the cap layer CP is embedded in the uppermost insulating layer OL are formed. However, at this time point, the memory layer ME covers the entire side wall of the pillar PL, and a part of the side surface of the channel layer CN is not in a state of being exposed from the memory layer ME.

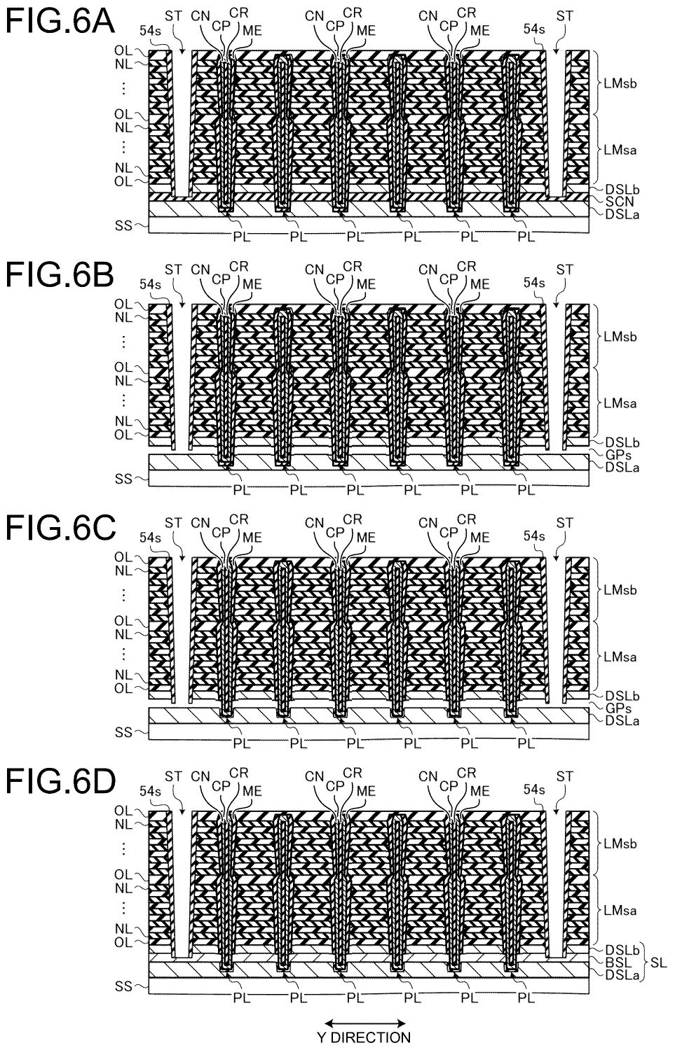

As illustrated in FIG. 6A, slits ST that penetrate the stacked bodies LMsb and LMsa and the upper source line DSLb and reach the intermediate sacrificial layer SCN are formed. In addition, insulating layers 54s are formed on the side walls of the slits ST facing each other in the Y direction. The slits ST also extend in the direction along the X direction in the stacked bodies LMsa and LMsb.

As illustrated in FIG. 6B, a removal liquid for the intermediate sacrificial layer SCN such as hot phosphoric acid is caused to flow through the slits ST whose side walls are protected by the insulating layers 54s, and the intermediate sacrificial layer SCN sandwiched between the lower source line DSLa and the upper source line DSLb is removed.

As a result, a gap layer GPs is formed between the lower source line DSLa and the upper source line DSLb. In addition, a part of the memory layers ME in the outer peripheral portions of the pillars PL is exposed in the gap layer GPs. At this time, since the side walls of the slits ST are protected by the insulating layers 54s, it is suppressed that the insulating layers NL in the stacked bodies LMsa and LMsb are also removed.

As illustrated in FIG. 6C, a chemical liquid is caused to appropriately flow into the gap layer GPs through the slits ST, and the block insulating layer BK, the charge storage layer CT, and the tunnel insulating layer TN (see FIG. 2B) of the memory layer ME exposed in the gap layer GPs are sequentially removed. As a result, the memory layers ME are removed from partial side walls of the pillars PL, and a part of the channel layers CN on the inner side is exposed in the gap layer GPS.

As illustrated in FIG. 6D, a source gas such as amorphous silicon is injected from the slits ST whose side walls are protected by the insulating layers 54s, and the gap layer GPs is filled with amorphous silicon or the like. In addition, the support substrate SS is heat-treated to polycrystallize the amorphous silicon loaded in the gap layer GPs, thereby forming the intermediate source line BSL containing polysilicon or the like.

As a result, a part of the channel layers CN of the pillars PL is connected to the source line SL on the side surfaces via the intermediate source line BSL.

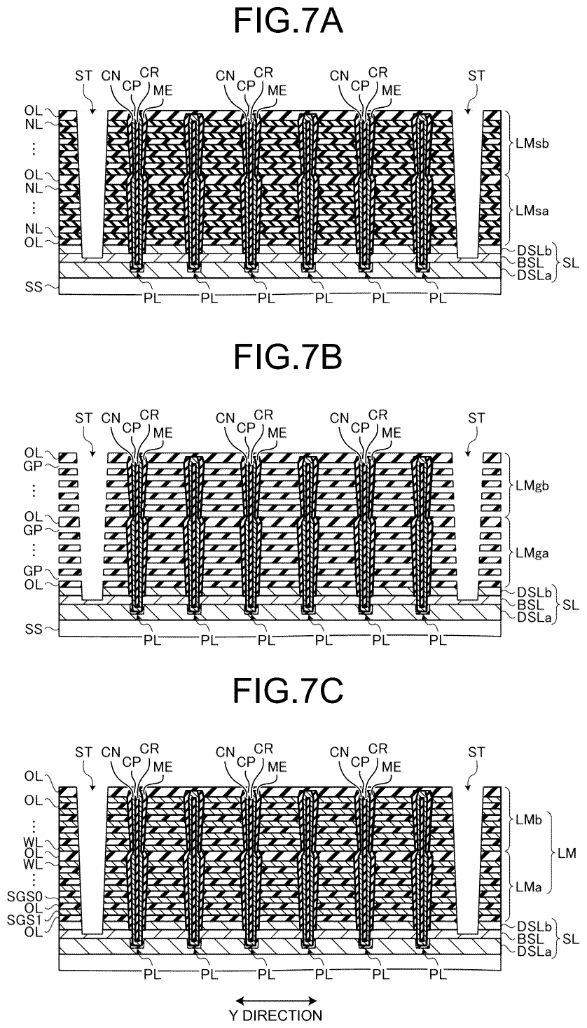

As illustrated in FIG. 7A, the insulating layers 54s on the side walls of the slits ST are temporarily removed.

As illustrated in FIG. 7B, a removal liquid for the insulating layers NL such as, for example, hot phosphoric acid is caused to flow into the stacked bodies LMsa and LMsb from the slits ST to remove the insulating layers NL of the stacked bodies LMsa and LMsb. As a result, stacked bodies LMga and LMgb including a plurality of gap layers GP from which the insulating layers NL between the insulating layers OL are removed are formed.

The stacked bodies LMga and LMgb including the plurality of gap layers GP have a fragile structure. The plurality of pillars PL supports such fragile stacked bodies LMga and LMgb. As a result, bending of the insulating layers OL remaining in the stacked bodies LMga and LMgb and distortion or collapse of the stacked bodies LMga and LMgb are suppressed.

As illustrated in FIG. 7C, a source gas of a conductive material such as tungsten or molybdenum is injected from the slits ST into the stacked bodies LMga and LMgb, and the gap layers GP of the stacked bodies LMga and LMgb are filled with the conductive material to form the plurality of word lines WL and the like. As a result, the stacked body LM including stacked bodies LMa and LMb in which the plurality of word lines WL and the like and the plurality of insulating layers OL are alternately stacked one by one is formed.

As described above, the treatment of forming the intermediate source line BSL from the intermediate sacrificial layer SCN and the treatment of forming the word lines WL from the insulating layers NL are also referred to as replacement treatment.

Thereafter, the insulating layers 54 are formed on the side walls of the slits ST, and the insulating layers 54 are filled with the conductive layers 24 to form the plate-like contacts LI. However, the insulating layers 54 or the like may be loaded in the slits ST without forming the conductive layers 24 to form the plate-like members.

Thereafter, grooves penetrating one or a plurality of conductive layers including the uppermost conductive layer of the stacked body LMb are formed, and the insulating layers 56 are loaded in the grooves to form the separation layers SHE that partition these conductive layers into the pattern of the select gate lines SGD.

In addition, the plurality of contacts CC reaching the word lines WL and the select gate lines SGD and SGS constituting the steps of the staircase structure of the staircase regions SR are formed from the upper side of the staircase regions SR.

In addition, the insulating layer 52 is formed on the upper surface of the stacked body LM, and the plugs CH connected to the pillars PL and plugs connected to the contacts CC are formed by penetrating the insulating layer 52. Further, the insulating layer 53 is formed on the insulating layer 52, and the bit line BL connected to the plugs CH, the upper layer wiring connected to the contacts CC via the plugs, and the like are formed. In addition, an electrode pad or the like for having electrical conduction with the peripheral circuits CBA is formed on the upper surface of the insulating layer 53.

Note that, for example, the plugs CH, the bit line BL, and the like may be collectively formed by using a dual damascene method or the like.

In addition, the peripheral circuits CBA are formed on the semiconductor substrate SB separate from the support substrate SS on which the stacked body LM is formed, and are covered with the insulating layer 40. In the insulating layer 40, contacts, vias, wiring, or the like that lead the peripheral circuits CBA to the surface of the insulating layer 40 are formed and connected to the electrode pad or the like formed on the upper surface of the insulating layer 40.

Subsequently, the support substrate SS and the semiconductor substrate SB are bonded to each other by the insulating layers 50 and 40, and the electrode pads in the insulating layers 50 and 40 are connected. Thereafter, the support substrate SS is removed to expose the source line SL, and the electrode film EL is connected via the insulating layer 60 in which the plugs PG are formed.

Thus, the semiconductor memory device 1 of the first embodiment is manufactured.

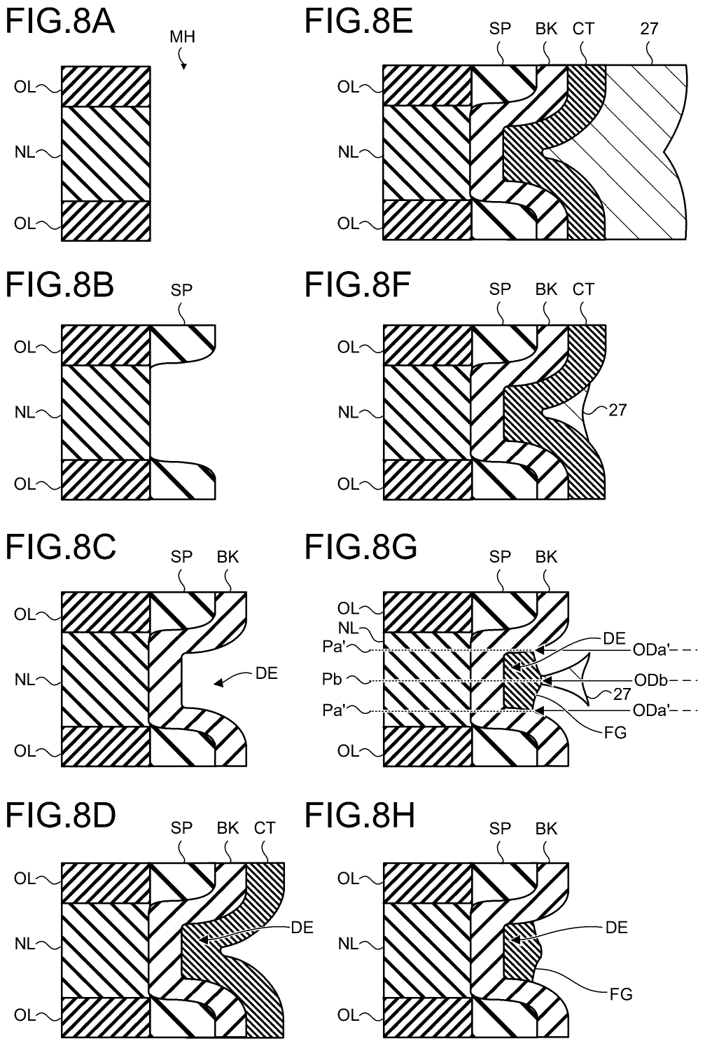

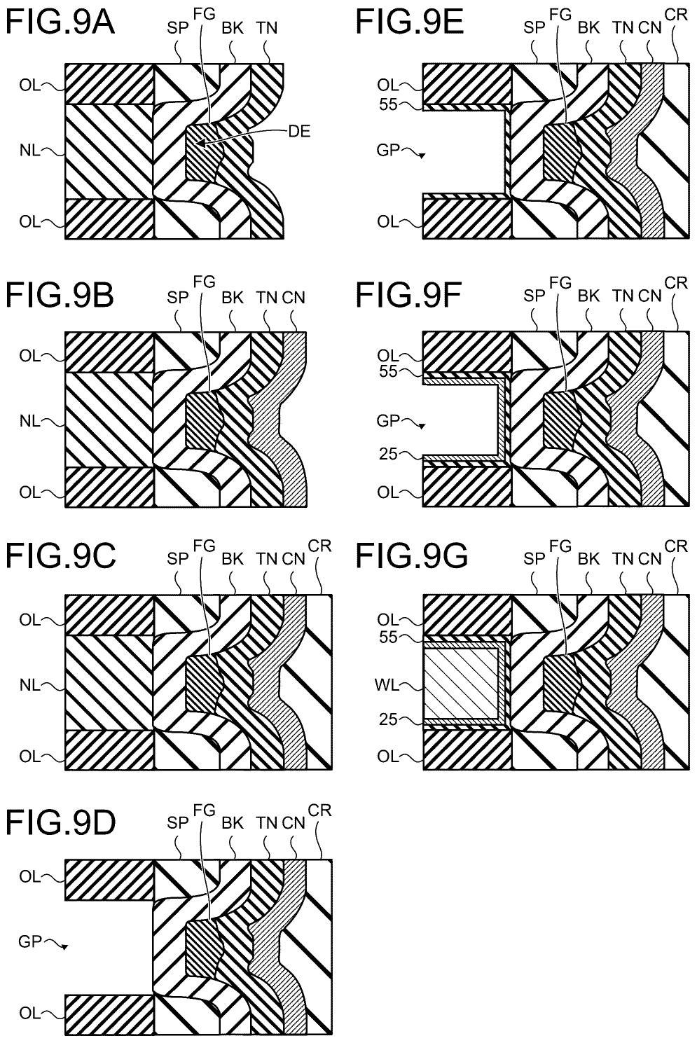

Next, details of a method for dividing the charge storage layer CT will be described with reference to FIGS. 8A to 9G. FIGS. 8A to 9G are enlarged cross-sectional views sequentially illustrating a part of a procedure of a method for forming the memory layer ME according to the first embodiment. FIGS. 8A to 9G illustrate a cross section of the side wall on one side of the memory hole MH at the height position of an arbitrary insulating layer NL that becomes the word line WL later.

As illustrated in FIG. 8A, the memory hole MH penetrating the stacked bodies LMsa and LMsb is formed by the treatment of FIG. 4B described above.

As illustrated in FIG. 8B, a silicon oxide layer or the like is selectively grown on the end surfaces of the insulating layers OL exposed on the side wall of the memory hole MH to form the spacer layer SP. As a result, the spacer layer SP covers substantially the entire end surfaces of the insulating layers OL. Note that the end portion of the spacer layer SP in the stacking direction may partially overlap the insulating layer NL.

As illustrated in FIG. 8C, the entire side wall of the memory hole MH is covered with a silicon oxide layer or the like to form the block insulating layer BK. At this time, for example, a silicon nitride layer or the like covering the entire side wall of the memory hole MH may be formed, and the silicon nitride layer or the like may be oxidized to form the block insulating layer BK that is a silicon oxide layer or the like. However, as described above, the block insulating layer BK may be a metal oxide layer in addition to a silicon oxide layer or the like, or may be a layer obtained by combining a silicon oxide layer and a metal oxide layer.

As a result, the block insulating layer BK covering the insulating layer NL exposed on the side wall of the memory hole MH and the spacer layer SP formed at the height position of the insulating layers OL is formed. The block insulating layer BK formed in this manner has a concave portion DE retracted toward the outer peripheral side of the memory hole MH with respect to the other portions at the height position of the insulating layer NL.

As illustrated in FIG. 8D, the entire side wall of the memory hole MH is continuously covered with a silicon nitride layer or the like, and the charge storage layer CT is formed on the surface of the block insulating layer BK. However, as described above, the charge storage layer CT may be a silicon layer, a metal oxide layer, or the like in addition to a silicon nitride layer.

Through the above treatment, the charge storage layer CT also has a shape retracted to the outer peripheral side of the memory hole MH with respect to the other portions at the concave portion DE of the block insulating layer BK formed at the height position of the insulating layer NL.

As illustrated in FIG. 8E, the charge storage layer CT on the side wall of the memory hole MH is covered with a sacrificial layer 27 such as an amorphous silicon layer. At this time, the layer thickness of the sacrificial layer 27 is adjusted according to the distance in the stacking direction of the concave portion DE of the block insulating layer BK so that the degree of retraction at the height position of the insulating layer NL is alleviated on the outermost surface of the sacrificial layer 27, that is, the surface facing the inside of the memory hole MH. Note that, the sacrificial layer 27 may be a silicon oxide layer, a carbon layer, a metal oxide layer such as a hafnium oxide layer, or the like in addition to an amorphous silicon layer.

As illustrated in FIG. 8F, the sacrificial layer 27 on the side wall of the memory hole MH is selectively reduced in thickness. As a result, the charge storage layer CT formed at the height positions of the insulating layers OL is exposed while leaving the sacrificial layer 27 formed at the retraction portion of the charge storage layer CT at the height position of the insulating layer NL. At this time, it is preferable to adjust the thickness reduction treatment condition of the sacrificial layer 27 so as to reduce the thickness reduction amount of the sacrificial layer 27 remaining at the retraction portion of the charge storage layer CT. As described above, the outermost surface of the remaining sacrificial layer 27, that is, the surface facing the inside of the memory hole MH is preferably located as close to the inside of the memory hole MH as possible.

As illustrated in FIG. 8G, the charge storage layer CT on the side wall of the memory hole MH is selectively reduced in thickness. As a result, the block insulating layer BK formed at the height positions of the insulating layers OL is exposed while leaving the retraction portion of the charge storage layer CT at the height position of the insulating layer NL. As a result, the fragment layer FG that is the retraction portion of the remaining charge storage layer CT is formed so as to be fitted into the concave portion DE of the block insulating layer BK.

At this time, it is preferable to adjust the thickness reduction treatment condition for the charge storage layer CT such that the outermost surface of the fragment layer FG, that is, the surface facing the inside of the memory hole MH is located on the outer peripheral side of the memory hole MH with respect to the exposed surface of the block insulating layer BK formed at the height positions of the insulating layers OL.

In addition, at this time, the vicinity of the center in the thickness direction of the insulating layer NL within the outermost surface of the fragment layer FG is protected by the sacrificial layer 27 remaining in the aforementioned treatment of FIG. 8F. As a result, the fragment layer FG has a shape in which the vicinity of the center in the thickness direction of the insulating layer NL protrudes to the inside of the memory hole MH with respect to both end portions in the stacking direction of the stacked bodies LMsa and LMsb.

As described above, when the thickness reduction treatment condition for the charge storage layer CT is adjusted, the thickness reduction treatment condition for the charge storage layer CT can be adjusted such that, for example, in the inner shape of the fragment layer FG, that is, in the surface facing the center side in the extending direction of the memory hole MH, the diameter at a height position Pa′ of each of both end portions facing the center of the memory hole MH in the stacking direction of the plurality of fragment layers FG is larger than the diameter at the height position Pb of the central part in the stacking direction of each fragment layer FG.

As a result, the fragment layer FG has an inner shape in which a distance ODa′ in the X direction at the height position Pa′ is larger than the distance ODb in the X direction at the height position Pb.

As illustrated in FIG. 8H, the sacrificial layer 27 remaining on the outermost surface of fragment layer FG is removed.

As illustrated in FIG. 9A, the entire side wall of the memory hole MH is covered with a silicon oxide layer or the like to form the tunnel insulating layer TN. However, as described above, the tunnel insulating layer TN may be a silicon oxynitride layer or the like in addition to a silicon oxide layer or the like.

Through the above treatment, the tunnel insulating layer TN also has a shape retracted to the outer peripheral side of the memory hole MH with respect to the other portions at the concave portion DE of the block insulating layer BK formed at the height position of the insulating layer NL. However, the degree of retraction of the tunnel insulating layer TN is alleviated by the fragment layer FG formed in the concave portion DE of the block insulating layer BK.

As illustrated in FIG. 9B, the channel layer CN is formed by covering the entire side wall of the memory hole MH with a semiconductor layer or the like. As a result, the channel layer CN also has a shape retracted to the outer peripheral side of the memory hole MH with respect to the other portions at the height position of the insulating layer NL, that is, the formation position of the fragment layer FG in the concave portion DE of the block insulating layer BK.

As illustrated in FIG. 9C, an oxide insulating layer or the like is loaded into the memory hole MH further inside the channel layer CN to form the core layer CR.

Thereafter, the treatment of FIGS. 4D to 5C is performed to form the pillar PL having the cap layer CP at the upper end portion. In addition, the intermediate source line BSL is formed by performing the treatment of FIGS. 6A to 6D, and the channel layer CN is connected to the source line SL on the side surface.

In addition, the treatment of FIGS. 7A to 7C is performed to replace the insulating layer NL with the word line WL or the like. Details are illustrated in FIGS. 9D to 9G below.

As illustrated in FIG. 9D, the insulating layer NL in the stacked bodies LMsa and LMsb is removed using hot phosphoric acid or the like. As a result, the gap layer GP is formed between the plurality of insulating layers OL. In addition, the upper and lower surfaces of the insulating layers OL and a part of the side wall of the pillar PL are exposed in the gap layer GP. Note that, more specifically, the side wall of the pillar PL exposed in the gap layer GP is an outer surface of the block insulating layer BK constituting the concave portion DE.

As illustrated in FIG. 9E, the upper and lower surfaces of the insulating layers OL exposed in the gap layer GP and the outer surface of the concave portion DE of the block insulating layer BK are covered with a layer having a dielectric constant higher than that of the silicon oxide layer such as an aluminum oxide layer to form the metal-containing layer 55.

As illustrated in FIG. 9F, the barrier metal layer 25 is formed by covering the surface of the metal-containing layer 55 formed in the gap layer GP with a titanium layer, a titanium nitride layer, a tantalum layer, a tantalum nitride layer, a molybdenum nitride layer, or the like.

As illustrated in FIG. 9G, a tungsten layer, a molybdenum layer, or the like is loaded into the gap layer GP further inside the barrier metal layer 25 to form the word line WL.

### (Overview)

In semiconductor memory devices such as a three-dimensional nonvolatile memory, the pitch between a plurality of word lines has been reduced. Interference between memory cells may occur as a result of a reduction in pitch between word lines. In addition, charges accumulated in a charge storage layer of the memory cell move to an adjacent memory cell, and the data holding characteristics of the memory cell may deteriorate. In order to suppress such inter-memory cell interference and deterioration of data holding characteristics, for example, it is effective to have a divided structure in which the charge storage layer is divided for each memory cell. The charge storage layer is formed over the entire side wall of the memory hole and then divided into individual fragment layers at the height positions of the word lines.

However, the individual fragment layers divided as described above may have an arc shape in which both end portions in the stacking direction of the stacked body protrude toward the inside of the pillar and the central part in the stacking direction is recessed. In this case, when data is written to the memory cell, a channel is formed between both end portions of the fragment layer in the stacking direction, and charges are concentrated in the central part of the fragment layer in the stacking direction, so that local writing occurs. As a result, the effective length of the fragment layer in the stacking direction is reduced, and data writing saturation is likely to occur.

With the semiconductor memory device 1 of the first embodiment, the tunnel insulating layer TN includes a portion in which the outer shape at the height position Pb located between both end portions in the thickness direction of each of the plurality of word lines WL and the select gate lines SGD and SGS, the height position Pb being the height position facing each of the plurality of fragment layers FG is the predetermined distance ODb in the direction along the X direction, and a portion in which the outer shape at the height position Pg located between the height positions Pa of both end portions of the word lines WL and the like and the height position Pb is the distance ODg larger than the distance ODb at the height position Pb in the direction along the X direction.

As a result, the fragment layer FG can be prevented from having an arc shape, and the fragment layer FG having a flatter inner surface can be obtained. Therefore, local write concentration on the fragment layer FG is suppressed, and the characteristics of the memory cell MC can be improved.

Note that variations of various memory layers having different shapes can be obtained by appropriately adjusting the method for forming the memory layer ME in the first embodiment described above. In first to third modifications described below, some examples of memory layers having different shapes will be described.

### (First Modification)

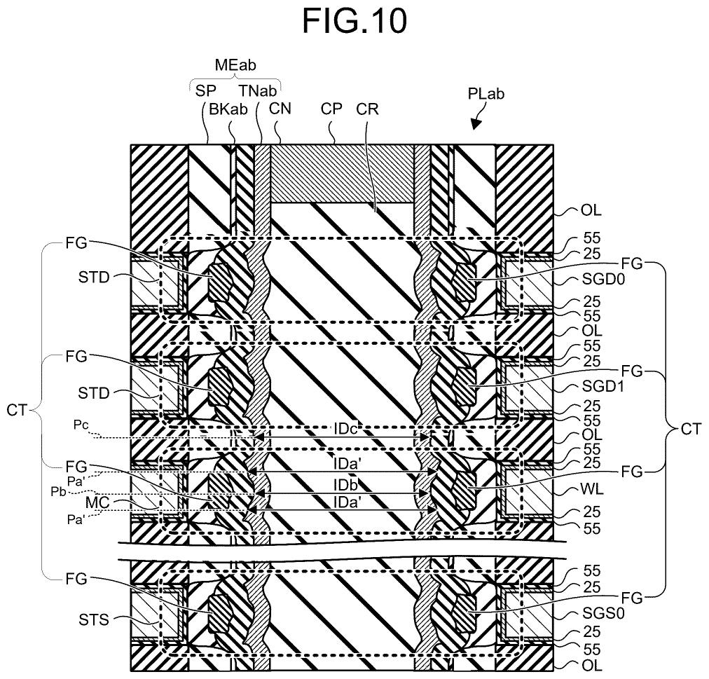

Next, a semiconductor memory device of a first modification of the first embodiment will be described with reference to FIG. 10. The semiconductor memory device of the first modification includes a tunnel insulating layer TNab having an inner shape having a high flatness than the tunnel insulating layer TN of the first embodiment described above.

Note that, in FIG. 10 described below, the same reference numerals are given to the same configurations as those of the first embodiment described above, and the description thereof may be omitted.

FIG. 10 is an enlarged cross-sectional view at a height position of a word line WL and select gate lines SGD and SGS of a pillar PLab included in a semiconductor memory device according to a first modification of the first embodiment.

As illustrated in FIG. 10, the pillar PLab of the first modification includes a memory layer MEab including a block insulating layer BKab and a tunnel insulating layer TNab instead of the memory layer ME of the first embodiment described above. The other layers of the memory layer MEab including the spacer layer SP and the charge storage layer CT including the fragment layers FG have the same configuration as those of the above-described first embodiment.

The block insulating layer BKab of the first modification has different layer thicknesses depending on the height position of the stacked body LM. More specifically, the layer thickness of the block insulating layer BKab at the height positions of the plurality of insulating layers OL is thinner than the layer thickness at the height positions of the plurality of word lines WL and select gate lines SGD and SGS. In addition, the block insulating layer BKab almost disappears between the individual insulating layers OL and the individual word lines WL and the select gate lines SGD and SGS.

As a result, the tunnel insulating layer TNab protrudes toward the block insulating layer BKab side at the height positions of the individual insulating layers OL, the individual word lines WL, and the select gate lines SGD and SGS. Accordingly, the outer shape of the tunnel insulating layer TNab has a shape protruding toward the outer peripheral side of the pillar PL with respect to the other portions at the height positions of the plurality of word lines WL and the select gate lines SGD and SGS.

Therefore, in the tunnel insulating layer TNab, the layer thickness at the height positions of the plurality of word lines WL and the select gate lines SGD and SGS is larger than the layer thickness at the height positions of the plurality of insulating layers OL. As a result, each fragment layer FG is substantially embedded in a tunnel insulating layer TNab portion protruding toward the outer peripheral side of the pillar PL.

At this time, at the height positions of the plurality of word lines WL and the select gate lines SGD and SGS, the total thickness of the block insulating layer BKab and the tunnel insulating layer TNab excluding the fragment layer FG is larger than the total thickness at the height positions of the plurality of insulating layers OL.

Since the block insulating layer BKab and the tunnel insulating layer TNab have the shapes as described above, flatness of the inner shape of the tunnel insulating layer TNab as a whole is higher than flatness of the inner shape of the tunnel insulating layer TN of the first embodiment described above, for example. Similarly, the flatness of both the outer shape and the inner shape of a channel layer CNab is larger than, for example, the flatness of the channel layer CN of the first embodiment described above as a whole.

At this time, when the shape of the pillar PLab as viewed from the stacking direction of the stacked body LM is, for example, a circle, the tunnel insulating layer TNab has an inner shape in which a difference between the diameter at the height position Pb facing each central part of each of fragment layers FGab in the stacking direction, the height position Pb being a height position located between both end portions in the thickness direction of each of the plurality of word lines WL and the select gate lines SGD and SGS and the diameter at a height position Pc of each of the plurality of insulating layers OL is smaller than a difference between diameters at the height positions Pb and Pc of the inner shape of the tunnel insulating layer TN of the first embodiment described above.

In addition, the tunnel insulating layer TNab has an inner shape in which a difference between the diameter at the height position Pa′ of each of both end portions on the side facing the tunnel insulating layer TNab in the stacking direction of the plurality of fragment layers FGab and the diameter at the height position Pc of each of the plurality of insulating layers OL is smaller than that in the case of the tunnel insulating layer TN of the first embodiment described above.

In addition, the tunnel insulating layer TNab has an inner shape in which distances IDa′, IDb, and IDc in the X direction at the height positions Pa′, Pb, and Pc are substantially equal to each other. At this time, the tunnel insulating layer TNab may have an inner shape in which a distance IDb in the X direction at the height position Pb is equal to or less than a distance IDc in the X direction at the height position Pc.

With the semiconductor memory device of the first modification, the total thickness of the block insulating layer BKab and the tunnel insulating layer TNab excluding the plurality of fragment layers FG at the height positions of the plurality of word lines WL and the select gate lines SGD and SGS is larger than the total thickness of the block insulating layer BKab and the tunnel insulating layer TNab at the height positions between the word lines WL and the like.

With such a configuration, the flatness of the tunnel insulating layer TNab is increased, and eventually, the write concentration in the fragment layer FG can be further reduced.

With the semiconductor memory device of the first modification, the tunnel insulating layer TNab includes a portion in which the inner shape at the height position Pc between each of the plurality of word lines WL and the select gate lines SGD and SGS is the predetermined distance IDc in the direction along the X direction, and a portion in which the inner shape at the height position Pb of each of the word lines WL and the like is the distance IDb equal to or less than the distance IDc at the above-described height position Pc in the direction along the X direction.

This indicates that flatness of the tunnel insulating layer TNab is further increased. As a result, the write concentration in the fragment layer FG can be further reduced.

With the semiconductor memory device of the first modification, the same effects as those of the semiconductor memory device 1 of the first embodiment described above are obtained.

### (Second Modification)

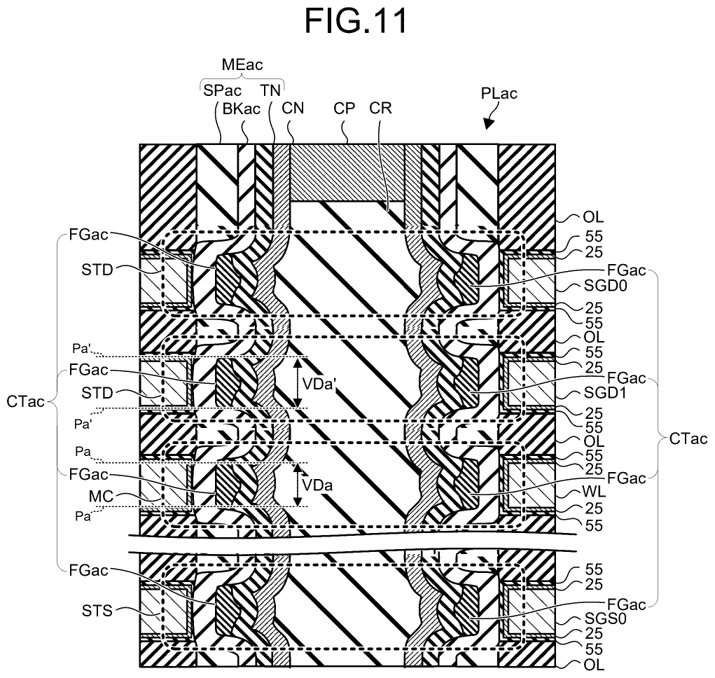

Next, a semiconductor memory device of a second modification of the first embodiment will be described with reference to FIG. 11. The semiconductor memory device according to the second modification is different from the semiconductor memory device according to the first embodiment described above in that the length of a fragment layer FGac in the stacking direction of the stacked body LM is longer than that of the fragment layer FG included in the charge storage layer CT according to the first embodiment described above.

Note that, in FIG. 11 described below, the same reference numerals are given to the same configurations as those of the first embodiment described above, and the description thereof may be omitted.

FIG. 11 is an enlarged cross-sectional view at a height position of a word line WL and select gate lines SGD and SGS of a pillar PLac included in the semiconductor memory device according to the second modification of the first embodiment.

As illustrated in FIG. 11, the pillar PLac of the second modification includes a memory layer MEac having a spacer layer SPac, a block insulating layer BKac, and a charge storage layer CTac including the fragment layers FGac instead of the memory layer ME of the first embodiment described above. The other layer including the tunnel insulating layer TN has the same configuration as that of the first embodiment described above.

The spacer layer SPac of the second modification has a shape in which the length in the stacking direction of the stacked body LM is shorter than that of the spacer layer SP of the first embodiment described above. That is, it is retracted in both directions in the stacking direction of the stacked body LM with respect to the individual word lines WL and the select gate lines SGD and SGS, and is not provided near both end portions of the individual insulating layers OL in the stacking direction.

As a result, the width of the retraction portion of the block insulating layer BKac at the height position of each of the word lines WL and the select gate lines SGD and SGS is widened, and the length of the fragment layer FGac in the stacking direction formed at the retraction portion of the block insulating layer BKac is also increased. At this time, the length of the fragment layer FGac in the stacking direction is preferably equal to or more than the thickness of each of the word lines WL and the select gate lines SGD and SGS.

That is, in the second modification, a distance VDa′ between the height positions Pa′ of both end portions on the side facing the tunnel insulating layer TN in the stacking direction of the plurality of fragment layers FGac is preferably larger than a distance VDa between the height positions Pa of both end portions in the stacking direction of the plurality of word lines WL and the select gate lines SGD and SGS.

With the semiconductor memory device of the second modification, the length of each of the plurality of fragment layers FGac in the stacking direction is equal to or greater than the thickness of each of the plurality of word lines WL and the select gate lines SGD and SGS. As a result, the effective length of the fragment layer FGac in the stacking direction can be increased, and local write concentration can be alleviated. In addition, with such a configuration, it is expected that write characteristics equivalent to those in the case of having a charge storage layer having a non-divided structure can be obtained.

With the semiconductor memory device of the second modification, the same effects as those of the semiconductor memory device 1 of the first embodiment described above are obtained.

### (Third Modification)

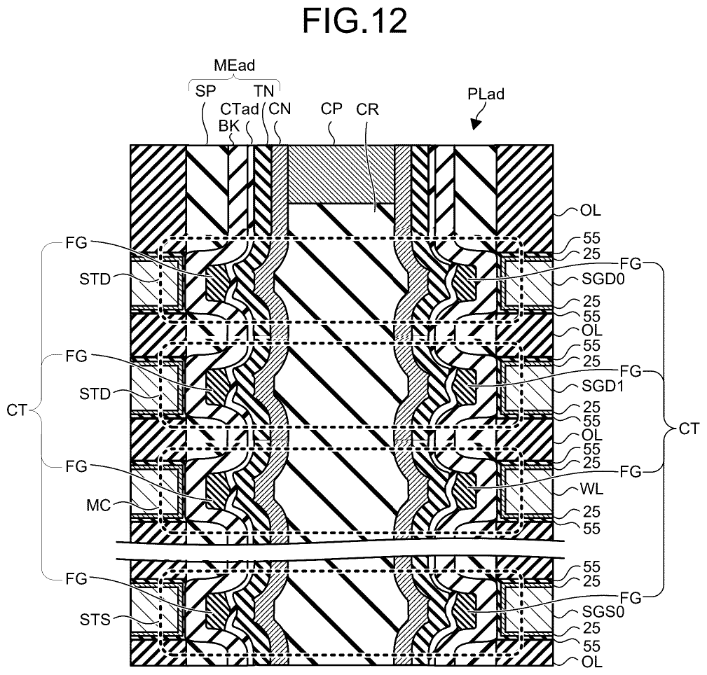

Next, a semiconductor memory device of a third modification of the first embodiment will be described with reference to FIG. 12. The semiconductor memory device of the third modification is different from the semiconductor memory device of the first embodiment described above in that the semiconductor memory device has a pseudo-divided structure in which the charge storage layer CT is pseudo-divided.

Note that, in FIG. 12 described below, the same reference numerals are given to the same configurations as those of the first embodiment described above, and the description thereof may be omitted.

FIG. 12 is an enlarged cross-sectional view at a height position of a word line WL and select gate lines SGD and SGS of a pillar PLad included in the semiconductor memory device according to the third modification of the first embodiment.

As illustrated in FIG. 12, the pillar PLad of the third modification includes a memory layer MEad having a charge storage layer CTad in addition to the spacer layer SP, the block insulating layer BK, and the charge storage layer CT including the fragment layers FG.

The charge storage layer CTad covers the block insulating layer BK at the height positions of the plurality of insulating layers OL, covers the fragment layers FG included in the charge storage layer CT at the height positions of the plurality of word lines WL and the select gate lines SGD and SGS, and continuously extends in the stacking direction of the stacked body LM. The charge storage layer CTad is, for example, a silicon nitride layer similarly to the charge storage layer CT.

At this time, the charge storage layer CTad is desirably made sufficiently thin so as not to cause deterioration in characteristics of memory cells in the charge storage layer having a non-divided structure, for example. As an example, the thickness of the charge storage layer CTad is at least less than the thickness of each fragment layer FG.

With such a configuration, the charge storage layer CTad connects the individual fragment layers FG to each other, and these fragment layers FG have a pseudo-divided structure.

The semiconductor memory device of the third modification further includes the charge storage layer CTad that includes the same material as the charge storage layer CT, is in contact with each surface of the plurality of fragment layers FG on the side facing the tunnel insulating layer TN, and extends in the stacking direction of the stacked body LM at a position between the tunnel insulating layer TN and the plurality of fragment layers FG and the block insulating layer BK.

As described above, since the individual fragment layers FG are connected by the thin charge storage layer CTad, data writing saturation can be made difficult to occur. In addition, by making the charge storage layer CTad sufficiently thin, for example, it is possible to suppress inter-memory cell interference and deterioration of data holding characteristics.

With the semiconductor memory device of the third modification, the same effects as those of the semiconductor memory device 1 of the first embodiment described above are obtained.

### (Other Modifications)

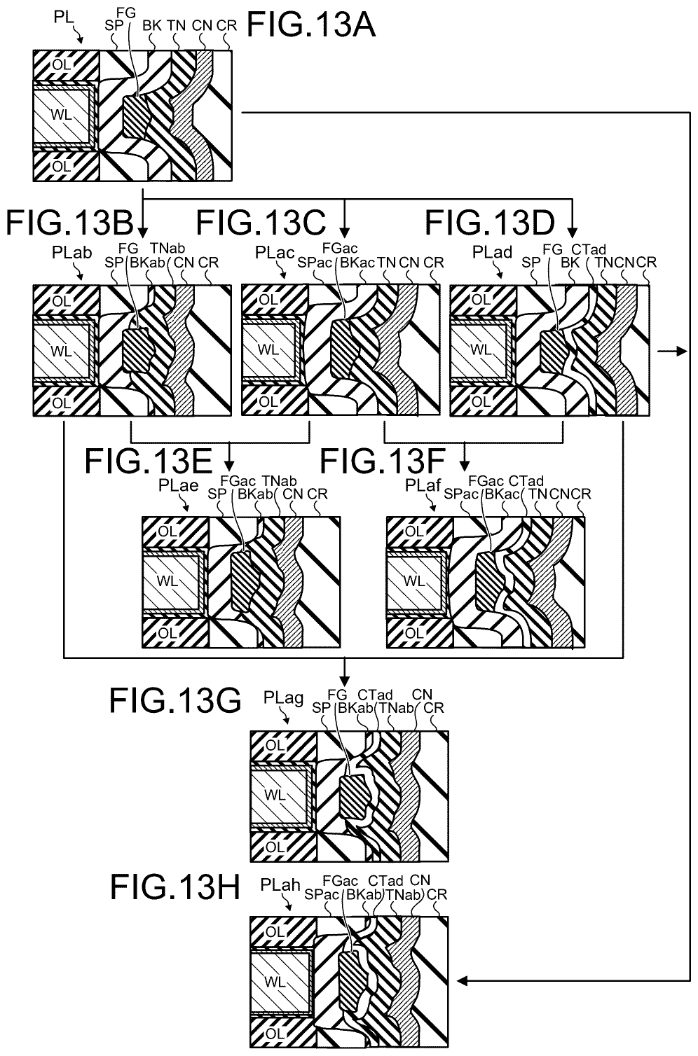

Note that the configurations described in the first embodiment and the first to third modifications described above can be appropriately combined and applied to the memory layer of the semiconductor memory device. Next, a memory layer obtained by combining the above-described configurations will be described with reference to FIGS. 13A to 13H.

FIGS. 13A to 13H are enlarged cross-sectional views illustrating configuration examples of pillars included in a semiconductor memory device according to other modifications of the first embodiment. Note that, in FIGS. 13A to 13H, the same reference numerals are given to the same configurations as those of the first embodiment or the first to third modifications described above, and the description thereof may be omitted.

FIG. 13A is an example of the pillar PL having the fragment layer FG of the first embodiment. The fragment layer FG of the first embodiment has an inner surface shape in which the central portion in the stacking direction of the stacked body LM is bulged in the center direction of the pillar PL with respect to both end portions in the stacking direction.

FIG. 13B is an example of the pillar PLab having the block insulating layer BKab and the tunnel insulating layer TNab of the first modification in addition to the configuration of the first embodiment. The layer thickness of the block insulating layer BKab and the tunnel insulating layer TNab of the first modification differs depending on the height position of the pillar PLab. As a result, the flatness degree of the tunnel insulating layer TNab of the first modification is increased.

FIG. 13C is an example of the pillar PLac having the fragment layer FGac of the second modification in addition to the configuration of the first embodiment. In the fragment layer FGac of the third modification, the length in the stacking direction of the stacked body LM is extended.

FIG. 13D is an example of the pillar PLad having the charge storage layer CTad of the third modification in addition to the configuration of the first embodiment. By having the charge storage layer CTad, the fragment layer FG of the third modification has a pseudo-divided structure.

FIG. 13E is an example of a pillar PLae having a configuration in which the configurations of the first embodiment and first and second modifications are combined. The pillar PLae illustrated in FIG. 13E includes the tunnel insulating layer TNab having an increased flatness degree and the fragment layer FGac having an extended length in the stacking direction of the stacked body LM.

FIG. 13F is an example of a pillar PLaf having a configuration in which the configurations of the first embodiment and second and third modifications are combined. The pillar PLaf illustrated in FIG. 13F includes the fragment layer FGac having an extended length in the stacking direction of the stacked body LM and having a pseudo-divided structure connected by the charge storage layer CTad.

FIG. 13G is an example of a pillar PLag having a configuration in which the configurations of the first embodiment and first and third modifications are combined. The pillar PLag illustrated in FIG. 13G includes the tunnel insulating layer TNab having an increased flatness degree and the fragment layer FG having a pseudo-divided structure connected by the charge storage layer CTad.

FIG. 13H is an example of a pillar PLah having a configuration in which the configurations of the first embodiment and first to third modifications are combined. The pillar PLah illustrated in FIG. 13H includes the fragment layer FGac having an inner surface shape in which the central portion in the stacking direction of the stacked body LM is bulged in the center direction of the pillar PL with respect to both end portions in the stacking direction, having an extended length in the stacking direction of the stacked body LM, and having a pseudo-divided structure connected by the charge storage layer CTad, and the tunnel insulating layer TNab having an increased flatness degree.

### Second Embodiment

Hereinafter, a second embodiment will be described in detail with reference to the drawings. A semiconductor memory device of the second embodiment is different from that of the first embodiment described above in the shape of fragment layers included in a charge storage layer.

In the drawings described below, the same reference numerals are given to the same configurations as those of the first embodiment described above, and the description thereof may be omitted.

### (Configuration Example of Pillar)

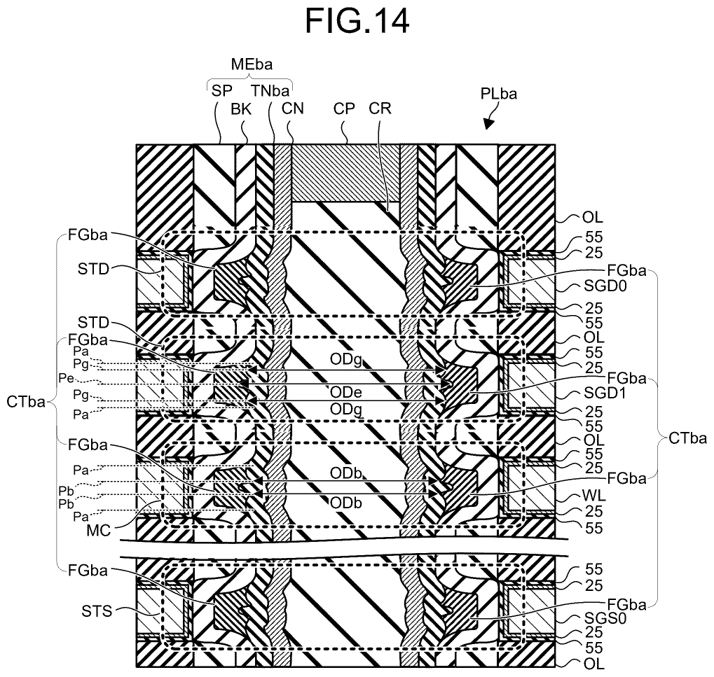

FIG. 14 is an enlarged cross-sectional view at a height position of a word line WL and select gate lines SGD and SGS of a pillar PLba included in the semiconductor memory device according to the second embodiment.

As illustrated in FIG. 14, the pillar PLba of the second embodiment includes a memory layer MEba including a charge storage layer CTba including fragment layers FGba and a tunnel insulating layer TNba instead of the memory layer ME of the first embodiment described above. The other layers of the memory layer MEba including the spacer layer SP and the block insulating layer BK have the same configuration as those of the above-described first embodiment.

The surface of each fragment layer FGba included in the charge storage layer CTba of the second embodiment facing the tunnel insulating layer TNba has a shape protruding toward the inside of the pillar PLba with respect to both end portions in the stacking direction at a position between the central part and both end portions in the stacking direction of the stacked body LM.

As a result, an outer shape of the tunnel insulating layer TNba is larger at a height position Pg of a portion where an inner shape of each fragment layer FGba is most retracted from the center in the extending direction of the pillar PLba, the height position Pg being a predetermined height position positioned between a height position Pa of each of both end portions in the stacking direction of the word lines WL and the select gate lines SGD and SGS and a height position Pb of a portion where the inner shape of each fragment layer FGba protrudes most toward the center in the extending direction of the pillar PLba, the height position Pb being a predetermined height position positioned between both end portions in a thickness direction of each of the plurality of word lines WL and the select gate lines SGD and SGS.

Note that, in the second embodiment, within the range of the height position between both end portions in the stacking direction of the fragment layers FGba, there is, for example, a plurality of height positions Pb corresponding to the portion where the inner shape of the fragment layer FGba protrudes most toward the center in the extending direction of the pillar PLba. Accordingly, the height positions Pg between the height position Pa and the height position Pb include, with reference to a predetermined word line WL, a height position Pg between the height position Pa on an upper surface of the word line WL in the stacking direction, that is, on an upper surface side and the height position Pb adjacent to the height position Pa in the stacking direction, and a height position Pg between the height position Pa on a lower surface of the reference word line WL in the stacking direction, that is, on a lower surface side and the height position Pb adjacent to the height position Pa in the stacking direction.

In addition, the surface of each fragment layer FGba facing the tunnel insulating layer TNba has a shape retracted toward the outside of the pillar PL with respect to both end portions in the stacking direction at the central part in the stacking direction of the stacked body LM. Accordingly, the surface of each fragment layer FGba facing the tunnel insulating layer TNba has a shape retracted toward the outside of the pillar PL with respect to the facing surface at the height positions Pa of both end portions in the stacking direction of the plurality of word lines WL and the like at a height position Pe of the central part in the stacking direction of the stacked body LM.

At this time, the retraction amount of the retraction portion of the fragment layer FGba at the height position Pe of the central part in the stacking direction of the stacked body LM may be larger than the retraction amount of the retraction portion of the fragment layer FGba at the height position Pg described above.

As a result, an outer shape of the tunnel insulating layer TNba is larger at the height position Pe facing each central part of each fragment layer FG in the stacking direction, the height position Pe being a predetermined height position positioned between both end portions in a thickness direction of each of the plurality of word lines WL and the select gate lines SGD and SGS than the outer shape at the height position Pa of each of both end portions in the stacking direction of the word lines WL and the select gate lines SGD and SGS.

That is, when the shape of the pillar PLba viewed from the stacking direction of the stacked body LM is, for example, a circle, the tunnel insulating layer TNba has an outer shape in which the diameter at the height position Pb is smaller than the diameter at the height position Pa. In addition, the tunnel insulating layer TNba has an outer shape in which the diameter at the height position Pe is larger than the diameter at the height position Pa.

In addition, the tunnel insulating layer TNba has an outer shape in which distances ODe and ODg in the X direction at the height positions Pe and Pg are larger than the distance ODb in the X direction at the height position Pb. Further, the tunnel insulating layer TNba may have an outer shape in which the distance ODe in the X direction at the height position Pe is larger than the distance ODg in the X direction at the height position Pg.

### (Method for Forming Memory Layer)

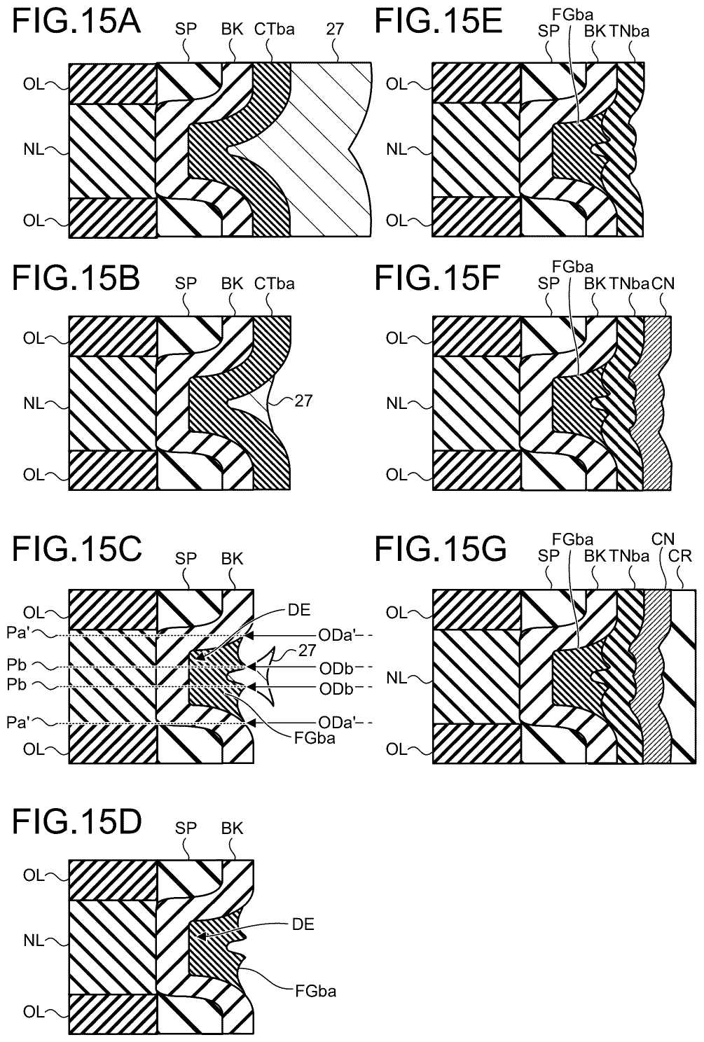

Next, a method for forming the memory layer MEba included in the semiconductor memory device of the second embodiment will be described with reference to FIGS. 15A to 15G. FIGS. 15A to 15G are enlarged cross-sectional views sequentially illustrating a part of a procedure of a method for forming the memory layer MEba according to the second embodiment.

As illustrated in FIG. 15A, the spacer layer SP, the block insulating layer BK, the charge storage layer CTba, and the sacrificial layer 27 are sequentially formed on the side wall of the memory hole MH. However, at this time point, the charge storage layer CTba is formed in the same manner as the charge storage layer CT of the first embodiment described above, and has the same shape.

As illustrated in FIG. 15B, the charge storage layer CT formed at the height position of the insulating layer OL is exposed while selectively reducing the thickness of the sacrificial layer 27 and leaving the sacrificial layer 27 formed at the retraction portion of the charge storage layer CT.

As illustrated in FIG. 15C, the block insulating layer BK formed at the height position of the insulating layer OL is exposed while selectively reducing the thickness of the charge storage layer CTba and leaving the retraction portion of the charge storage layer CT to form the fragment layer FGba. At this time, it is preferable to adjust the thickness reduction treatment condition for the charge storage layer CTba so that the position of the outermost surface of the fragment layer FGba substantially coincides with the position of the outermost surface of the block insulating layer BK exposed at the height position of the insulating layer OL when viewed from the stacking direction of the stacked bodies LMsa and LMsb.

As a result, when the thickness reduction treatment condition for the charge storage layer CT is adjusted, the thickness reduction treatment for the charge storage layer CTba is stopped before, for example, in the inner shape of the fragment layer FGba, that is, in the surface facing the center side in the extending direction of the memory hole MH, the diameter at the height position Pa′ of each of both end portions facing the center of the memory hole MH in the stacking direction of the plurality of fragment layers FGba is larger than the diameter at the center position of each fragment layer FGba in the stacking direction, that is, at the height position between the two height positions Pb. More preferably, the treatment is stopped before the diameter at the height positions Pa′ of both end portions of each fragment layer FGba in the stacking direction becomes larger by a predetermined distance or more with respect to the diameter at the height position Pb of the most protruding portion of each fragment layer FGba.

In addition, as a result, on the outermost surface of the fragment layer FGba, a shape in which the center position protected by the sacrificial layer 27 is most retracted is obtained. In addition, on the outermost surface of the fragment layer FGba, a shape in which positions between both end portions and the center position in the stacking direction are retracted is obtained. At this time, the fragment layer FGba may have an inner shape in which the distance ODa′ in the X direction at the height position Pa′ is substantially equal to the distance ODb in the X direction at the height position Pb. In addition, at this time, among these retraction portions of the fragment layer FGba, the retraction amount at the center position of the fragment layer FGba may be larger than the retraction amount at the position between both end portions and the center position in the stacking direction.

As illustrated in FIG. 15D, the remaining sacrificial layer 27 is removed.

As described below, the subsequent treatment is performed similarly to the treatment of FIG. 9A and the subsequent drawings of the first embodiment described above.

As illustrated in FIG. 15E, the tunnel insulating layer TNba covering the block insulating layer BK and fragment layer FGba is formed. In addition, the channel layer CN covering the tunnel insulating layer TNba is formed. Further, the core layer CR is loaded into the memory hole MH.

Thus, the spacer layer SP, the memory layer MEba, the channel layer CN, and the core layer CR are formed in the memory hole MH. The subsequent treatment is performed in the same manner as in the first embodiment described above.

### (Overview)

With the semiconductor memory device of the second embodiment, the tunnel insulating layer TNba includes a portion in which the outer shape at the height position Pb located between both end portions in the thickness direction of each of the plurality of word lines WL and the select gate lines SGD and SGS is the predetermined distance ODb in the direction along the X direction, and a portion in which the outer shape at the height position Pg located between the height positions Pa of both end portions of the word lines WL and the like is the distance ODg larger than the distance ODb at the height position Pb described above in the direction along the X direction.

As a result, it is possible to prevent the inner surface of the fragment layer FGba from having an arc shape. Therefore, local write concentration on the fragment layer FGba is suppressed, and the characteristics of the memory cell MC can be improved.

With the semiconductor memory device of the second embodiment, the tunnel insulating layer TNba has a portion located at the center in the thickness direction of each of the plurality of word lines WL and the select gate lines SGD and SGS and having the distance ODe larger than the distance ODg described above in the direction along the X direction. In addition, the portion of the fragment layer FGba at the height position Pb is disposed on both sides in the stacking direction of the portion corresponding to the distance ODe. As a result, it is possible to dispose a plurality of concaves and convexes on the inner surface of the fragment layer FGba to disperse the region where the write concentration occurs.

### (Other Modifications)

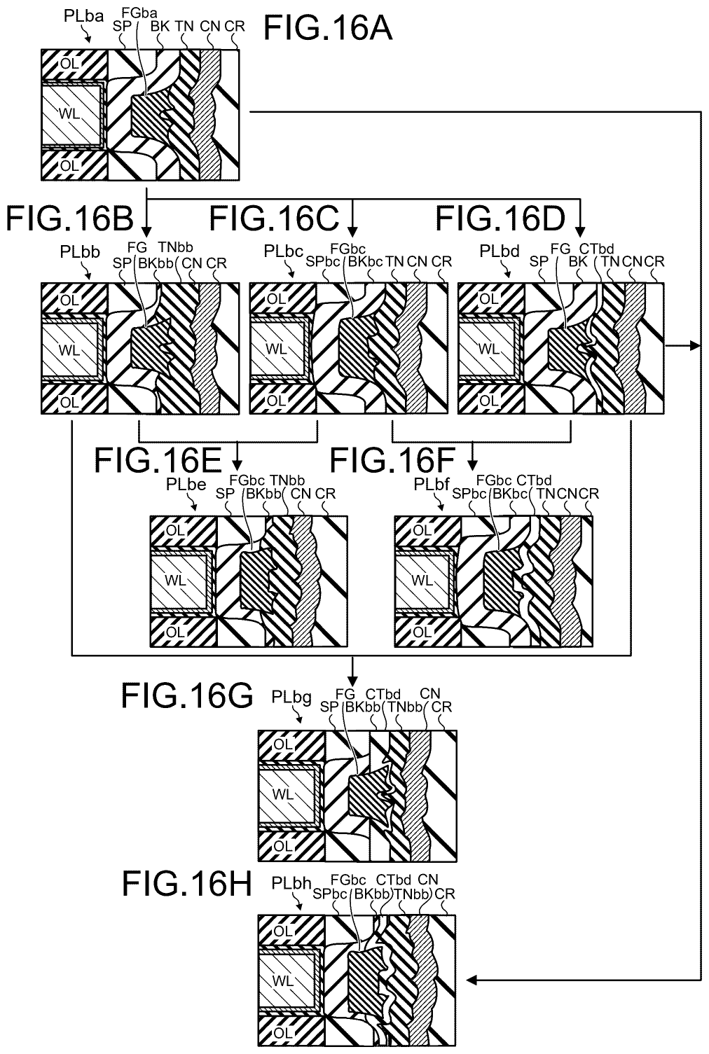

The configurations described in the first to third modifications of the first embodiment described above can be appropriately combined and applied to the memory layer of the semiconductor memory device of the second embodiment. Next, a memory layer obtained by combining the above-described configurations will be described with reference to FIGS. 16A to 16H.

FIGS. 16A to 16H are enlarged cross-sectional views illustrating configuration examples of pillars included in a semiconductor memory device according to other modifications of the second embodiment. Note that, in FIGS. 16A to 16H, the same reference numerals are given to the same configurations as those of the second embodiment described above, and the description thereof may be omitted.

FIG. 16A is an example of the pillar PLba having the fragment layer FGba of the second embodiment. The fragment layer FGba of the second embodiment includes an inner surface having a plurality of concaves and convexes in the stacking direction of the stacked body LM.

FIG. 16B is an example of a pillar PLbb having a configuration corresponding to the first modification of the first embodiment described above in addition to the configuration of the second embodiment. The layer thickness of a block insulating layer BKbb and a tunnel insulating layer TNbb of FIG. 16B differs depending on the height position of the pillar PLbb. As a result, the flatness degree of the tunnel insulating layer TNbb of FIG. 16B is increased.

FIG. 16C is an example of a pillar PLbc having a configuration corresponding to the second modification of the first embodiment described above in addition to the configuration of the second embodiment. The width of the retraction portion of a block insulating layer BKbc of FIG. 16C at the height position of each of the word lines WL and the select gate lines SGD and SGS is widened, and the length of a fragment layer FGbc in the stacking direction of the stacked body LM is extended.

FIG. 16D is an example of a pillar PLbd having the charge storage layer CTad of the third modification in addition to the configuration of the first embodiment. By having the charge storage layer CTad, the fragment layer FG of the third modification has a pseudo-divided structure.

FIG. 16E is an example of a pillar PLbe having a configuration in which the configurations of the second embodiment and first and second modifications of the first embodiment described above are combined. The pillar PLbc illustrated in FIG. 16E includes the tunnel insulating layer TNbb having an increased flatness degree and the fragment layer FGbc having an extended length in the stacking direction of the stacked body LM.

FIG. 16F is an example of a pillar PLbf having a configuration in which the configurations of the second embodiment and second and third modifications of the first embodiment described above are combined. The pillar PLbf illustrated in FIG. 16F includes the fragment layer FGbc having an extended length in the stacking direction of the stacked body LM and having a pseudo-divided structure connected by a charge storage layer CTbd.

FIG. 16G is an example of a pillar PLbg having a configuration in which the configurations of the second embodiment and first and third modifications of the first embodiment described above are combined. The pillar PLbc illustrated in FIG. 16G includes the tunnel insulating layer TNbb having an increased flatness degree and the fragment layer FG having a pseudo-divided structure connected by the charge storage layer CTbd.

FIG. 16H is an example of a pillar PLbh having a configuration in which the configurations of the second embodiment and first to third modifications of the first embodiment described above are combined. The pillar PLbh illustrated in FIG. 16H includes the fragment layer FGac having an inner surface shape in which the central portion in the stacking direction of the stacked body LM is bulged in the center direction of the pillar PL with respect to both end portions in the stacking direction, having an extended length in the stacking direction of the stacked body LM, and having a pseudo-divided structure connected by the charge storage layer CTbd, and the tunnel insulating layer TNab having an increased flatness degree.

### Other Embodiments

In the first and second embodiments and the first to third modifications described above, the semiconductor memory device 1 includes the stacked body LM having a two-tier structure in which two stacked bodies LMa and LMb are stacked up and down. However, the configuration of the stacked body is not limited to two tiers, and may be one tier or three tiers or more.

In addition, in the first and second embodiments and first to third modifications described above, the pillars PL or the like are connected to the source line SL on the side surfaces of the channel layers CN, but it is not limited thereto. For example, the pillar may be configured to be connected to the source line at the lower end portion of the channel layer by removing the memory layer on the bottom surface of the pillar.

In addition, in the first and second embodiments and first to third modifications described above, the peripheral circuits CBA and CUA are disposed above or below the stacked body LM. However, the peripheral circuit may be disposed in the same layer as the stacked body. In this case, the stacked body can be formed at a position different from the peripheral circuit on the semiconductor substrate on which the peripheral circuit is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers is stacked apart from each other; and
a pillar that extends in the stacked body in a stacking direction of the stacked body,
wherein
the pillar includes
a semiconductor layer extending in the stacking direction in the stacked body,
first and second insulating layers sequentially covering a side wall of the semiconductor layer from a semiconductor layer side, and
a plurality of fragment layers each of that is a third insulating layer scattered at height positions of the plurality of conductive layers interposed between the first and second insulating layers, the third insulating layer containing a material different from a material of the first and second insulating layer, and
the first insulating layer includes
a first portion in which an outer shape at a first height position located between both end portions in a thickness direction of each of the plurality of conductive layers is a first distance in a first direction along the plurality of conductive layers, the first portion being located at a height position facing each of the plurality of fragment layers, and
a second portion in which an outer shape at a second height position located between height positions of the both end portions of the plurality of conductive layers and the first height position is a second distance larger than the first distance in the first direction, the second portion being located at the height position facing each of the plurality of fragment layers.

2. The semiconductor memory device according to claim 1, wherein
the second portion is located at a height position of a center in a thickness direction of each of the plurality of conductive layers.

3. The semiconductor memory device according to claim 1, wherein
the first insulating layer includes a third portion located at a height position of a center in a thickness direction of each of the plurality of conductive layers and being a third distance larger than the first distance in the first direction.

4. The semiconductor memory device according to claim 3, wherein
the second portion is disposed on both sides of the third portion in the stacking direction.

5. The semiconductor memory device according to claim 1, wherein
a total thickness of the first and second insulating layers excluding the plurality of fragment layers at a height position of each of the plurality of conductive layers is larger than a total thickness of the first and second insulating layers at a height position between the plurality of conductive layers.

6. The semiconductor memory device according to claim 5, wherein
the first insulating layer includes
a fourth portion in which an inner shape at a height position between each of the plurality of conductive layers is a fourth distance in the first direction, and
a fifth portion in which an inner shape at a height position of each of the plurality of conductive layers is a fifth distance equal to or less than the fourth distance in the first direction.

7. The semiconductor memory device according to claim 1, wherein
a length of each of the plurality of fragment layers in the stacking direction is equal to or more than a thickness of each of the plurality of conductive layers.

8. The semiconductor memory device according to claim 1, wherein
the pillar further includes a fourth insulating layer containing a same material as the material of the third insulating layer and extending in the stacking direction at a position between the first insulating layer and both the plurality of fragment layers and the second insulating layer in contact with each surface of the plurality of fragment layers on a side facing the first insulating layer.

9. The semiconductor memory device according to claim 8, wherein
the fourth insulating layer has a substantially equal layer thickness at a height position between each of the plurality of conductive layers and a height position above an uppermost conductive layer of the plurality of conductive layers.

10. The semiconductor memory device according to claim 1, wherein
the first and second insulating layers are oxide layers, and
the plurality of fragment layers is a nitride layer.

11. The semiconductor memory device according to claim 1, wherein
the semiconductor layer is a channel layer,
the first insulating layer is a tunnel insulating layer,
the second insulating layer is a block insulating layer, and
the plurality of fragment layers is a charge storage layer.

12. A method for manufacturing a semiconductor memory device, the method comprising:
forming a stacked body in which a plurality of sacrificial layers is stacked apart from each other; and
forming a pillar that extends in the stacked body in a stacking direction of the stacked body, the pillar including
a semiconductor layer extending in the stacking direction in the stacked body,
first and second insulating layers sequentially covering a side wall of the semiconductor layer from a semiconductor layer side, and
a plurality of fragment layers each of that is a third insulating layer scattered at height positions of the plurality of sacrificial layers interposed between the first and second insulating layers, the third insulating layer containing a material different from a material of the first and second insulating layer, wherein
the forming the pillar includes
forming a hole extending in the stacked body in the stacking direction,
forming the second insulating layer such that an inner shape at a height position between each of the plurality of sacrificial layers is narrower than an inner shape at a height position of each of the plurality of sacrificial layers in a first direction along the plurality of sacrificial layers,
forming the third insulating layer containing the material different from the material of the first and second insulating layers and having a concave portion at the height position of each of the plurality of sacrificial layers by continuously covering the second insulating layer along the inner shape of the second insulating layer,
forming a protective layer filled into the concave portion of the third insulating layer,
forming the plurality of fragment layers, by removing the third insulating layer at the height position between each of the plurality of sacrificial layers to expose the second insulating layer, protecting an inner surface of the third insulating layer at the height position of each of the plurality of sacrificial layers with the protective layer, and retracting the inner surface of the third insulating layer to a position closer to a side wall of the hole with respect to an inner surface of the second insulating layer exposed at the height position between each of the plurality of sacrificial layers,
after removing the protective layer, forming the first insulating layer covering the plurality of fragment layers and the second insulating layer exposed at the height position between each of the plurality of sacrificial layers, and
forming the semiconductor layer covering the first insulating layer.

13. The method for manufacturing a semiconductor memory device according to claim 12, wherein
the forming the plurality of fragment layers includes
retracting the inner surface of the third insulating layer at the height position of each of the plurality of sacrificial layers until a distance in the first direction of an inner shape at a height position of an end portion of each of the plurality of fragment layers in the stacking direction is greater than a distance in the first direction of an inner shape at a predetermined height position between the end portions of each of the plurality of fragment layers.

14. The method for manufacturing a semiconductor memory device according to claim 12, wherein
the forming the plurality of fragment layers includes
stopping retraction of the inner surface of the third insulating layer at the height position of each of the plurality of sacrificial layers before a distance in the first direction of an inner shape at a height position of an end portion of each of the plurality of fragment layers in the stacking direction is greater than a distance in the first direction of an inner shape at a height position of a center of each of the plurality of fragment layers in the stacking direction.

15. The method for manufacturing a semiconductor memory device according to claim 13, wherein
the forming the plurality of fragment layers includes
removing the protective layer to expose the concave portion remaining in each of the plurality of fragment layers.

16. The method for manufacturing a semiconductor memory device according to claim 12, wherein
the forming the second insulating layer includes
forming a plurality of spacer layers serving as a base of the second insulating layer on a side wall of the hole at the height position between each of the plurality of sacrificial layers to make the inner shape of the second insulating layer at the height position between each of the plurality of sacrificial layers narrower than the inner shape at the height position of each of the plurality of sacrificial layers in the first direction.
